(19) United States
(12) Patent Application Publication
(10) Pub. No.: US 2008/0123698 A1
(43) Pub. Date: May 29, 2008

(54) Tb-DOPED LUMINESCENT COMPOUND, LUMINESCENT COMPOSITION AND LUMINESCENT BODY CONTAINING THE SAME, LIGHT EMITTING DEVICE AND SOLID-STATE LASER DEVICE

(75) Inventors: Masahiro Takata, Kanagawa-ken (JP); Masayuki Suzuki, Kanagawa-ken (JP); Junichi Mori, Minamiashigara-shi (JP); Tomotake Ikada, Kanagawa-ken (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Tokyo (JP)

(21) Appl. No.: 11/773,312

(22) Filed: Jul. 3, 2007

(30) Foreign Application Priority Data
Jul. 3, 2006 (JP) 2006-183687

(51) Int. Cl. H01S 5/026; C01F 17/00; C09K 11/02; H01L 33/00

(52) U.S. Cl. 372/22; 423/263; 252/301.36; 257/98; 257/E33.061

(57) ABSTRACT

A Tb-doped luminescent compound contains Tb and at least two kinds of metal elements other than Tb, and emits light by irradiation with excitation light. In the Tb-doped luminescent compound, the concentration of Tb with respect to the total number of moles of all of the metal elements including Tb is within the range of more than 3.75 mol % to 20.625 mol % inclusive.

### BACKGROUND OF THE INVENTION

1. Field of the Invention

The present invention relates to a Tb-doped luminescent compound, a luminescent composition containing the Tb-doped luminescent compound, and a luminescent body containing the Tb-doped luminescent compound. Further, the present invention relates to a light emitting device using the luminescent body and a solid-state laser device using the luminescent body.

2. Description of the Related Art

Research is widely conducted on luminescent compounds doped with Tb ions as luminescent center ions, such as Tb:YAG, represented by the general formula: TbₓY₃−Al₅O₁₂. Such luminescent compounds are studied as fluorescent materials having high fluorescence efficiency.

In U.S. Pat. No. 5,037,577, a method for producing Tb:YAG fine particles by using a hydrothermal synthesis method is disclosed. In U.S. Pat. No. 5,037,577, Tb:YAG represented by the above general formula, where x=0.05(C(Tb/A)=approximately 1.7 mol %), x=0.15(C(Tb/A)=5 mol %), x=0.3(C(Tb/A)=approximately 10 mol %), x=1.0(C(Tb/A)=approximately 33 mol %), x=2.0(C(Tb/A)=approximately 67 mol %) and x=3.0(C(Tb/A)=100 mol %), were actually prepared (please refer to Table 1 in page 5 of U.S. Pat. No. 5,037,577). In the specification of the present application, C(Tb/A) is used as parameter indicating the concentration of Tb in A-sites (including Tb), which are eight-coordination sites of garnet structure (hereinafter, the concentration of Tb is also referred to as a Tb concentration).

U.S. Pat. No. 5,037,577 discloses the feature that prepared Tb:YAG with x=0.15(C(Tb/A)=5 mol %) emits green fluorescence by irradiation with ultraviolet light having a wavelength within the range of 254 to 366 nm as excitation light (please refer to page 4, column 8, line 31 in U.S. Pat. No. 5,037,577). However, luminescence characteristics, such as the intensity of luminescence and the fluorescence lifetime, of each of the prepared Tb:YAG were not evaluated.

In U.S. Pat. No. 5,037,577, there are descriptions that it is well known, as a conventional technique, that Tb:YAG efficiently emits fluorescence when the value of x is x=0.15(C(Tb/A) 5 mol %) (please refer to page 1, column 2, line 11 in U.S. Pat. No. 5,037,577).

Table 1 is a list of well-known literature (non-patent literature documents 1 through 24) on fundamental studies on single crystals of Tb:YAG and polycrystalline ceramic materials thereof. Further, Table 1 shows Tb concentrations C(Tb/A) (the unit is mol % unless otherwise specified) described in the non-patent literature documents. In all of the non-patent literature documents except non-patent literature document 14, the Tb concentrations C(Tb/A) in prepared Tb:YAG are 10 mol % or less.

TABLE 1

| Non-Patent Literature Document | Tb Concentration |
|---|---|
| 1. D. J. Robbins, B. Cockayne, B. Lent and J. L. Glasper, J. Electrochem. Soc., 126 (1979) 1556. | 0.1~10% |
| 2. D. J. Robbins, B. Cockayne, A. G. Cullis and J. L. Glasper, J. Electrochem. Soc., 129 (1982) 816. | 1% |
| 3. W. F. van der Weg, T. J. A. Popma and A. T. Vink, J. Appl. Phys., 57 (1985) 5450. | 0.001%, 10% |
| 4. R. Bayerer, J. Heber and D. Mateika, Z. Phys. B., 64 (1986) 201. | 0.1%, 10% |
| 5. K. Ohno and T. Abe, J. Electrochem. Soc., 133 (1986) 638. | 0.1%, 5% |
| 6. M. S. Scholl and J. R. Trimmier, J. Electrochem. Soc., 133 (1986) 643. | 0.013%, 0.3%, 0.5%, 1% |
| 7. X. Liu, X. Wang and Z Wang, Phys. Rev. B., 39 (1989) 10633. | Ce-doped Tb: YAG, |
| | Ce/Tb = 0/1~1/1 |
| 8. N. Bodenschatz, R. Wannemacher, J. Heber and D. Mateika, J. Lumin., 47 (1991) 159. | 0.1%, 10% |
| 9. K. Richter, R. Wannemacher and J. Heber, J. Lumin., 47 (1991) 169. | 1% |
| 10. A. P. Dodokin, A. M. Kevorkov, D. D. Perlov and A. A. Sorokin, Cryst. Res. Tech., 26 (1991) 803. | 0.008%, 0.35%, 0.57%, |
| | 0.76%, 1% |
| 11. K. Ohno and T. Abe, J. Electrochem. Soc., 141 (1994) 1252. | 5% |
| 12. R. P. Rao, J. Electrochem. Soc., 143 (1996) 189. | 5% |
| 13. Y. Hakuta, K. Seino, H. Ura, T. Adcshiri, H. Takizawa and K. Arai, J. Mater. Chem., 9 (1999) 2671. | 5% |
| 14. S. Ganschow, D. Klimm, P. Reiche and R. Uecker, Cryst. Res. Tech., 34 (1999) 615. | 100% (Tb3Al5O12) |
| 15. Y. C. Kang, I. W. Lenggoro, S. B. Park, K. Okuyama, J. Phys. Chem. Sol., 60 (1999) 1855. | 0.2~4% |
| 16. J. Y. Choe, D. Ravichandran, S. M. Blomquist, K. W. Kirchner, E. W. Forsythe and D. C. Morton, | 1%, 2%, 3%, 4%, 5% |
| J. Lumin., 93 (2001) 119. | |
| 17. U. V. Valiev, U. R. Rustamov, B. Y. Sokolov, V. Nekvasil, R. A. Rupp, M. Fally and I. Amin, | 5 wt % |
| Phys. Stat. Sol. (b)., 231 (2002) 98. | |
| 18. J. Zhang, J. Ning, X. Liu, Y. Pan and L. Huang, Mater. Lett., 57 (2003) 3077. | 0.5%, 1.0%, 3.0%, |
| | 5.0%, 7.0% |
| 19. J. Zhang, J. Ning, X. Liu, Y. Pan and L. Huang, Mater. Res. Bull., 38 (2003) 1249. | 5% |
| 20. Y. Hakuta, T. Haganuma, K. Sue, T. Adschiri and K. Arai, Mater. Res. Bull., 38 (2003) 1257. | 10% |
| 21. J. L. Kennedy and N. Djeu, J. Lumin., 101 (2003) 147. | Yb-doped Tb: YAG, |
| | Yb/Tb = 10/0, 10/1, 10/2 |
| 22. R. A. Rodriguez-Rojas, E. D. Rosa-Cruz, L. A. Diaz-Torres, P. Salas, R. Melendrez, M. Barboza-Flores, | 2%, 4%, 8% |
| M. A. Meneses-Nave, O. Barbosa-Garcia, Opt. Mater., 25 (2004) 285. | |
| 23. D. Hreniak, W. Strek, P. Mazur, R. Pazik, M. Zabkowska-Waclawek, Opt. Mater., 26 (2004) 117. | 0.2%, 1%, 2%, 4%, 10% |
| 24. X. Ki, H. Liu, J. Wang, H. Cui, S. Yang and I. R. Boughton, J. Phys. Chem. Sol., 66 (2005) 201. | 0.67% |

In the list of Table 1, the concentration of Tb and the luminescence characteristic were evaluated only in non-patent literature documents 3, 18 and 23. These non-patent literature documents describe only data obtained when the Tb concentration C(Tb/A) was less than or equal to 10 mol %.

As described above, it has been conventionally believed that from the viewpoint of the intensity of fluorescence, it is preferable that the Tb concentration C(Tb/A) is less than or equal to 10 mol %.

In the list of Table 1, only non-patent literature document 14 reports Tb:YAG having a Tb concentration C(Tb/A) exceeding 10 mol %. In non-patent literature document 14, only a single crystal of Tb:YAG having a Tb concentration C(Tb/A) of 100 mol % was actually prepared by using the Czochralski method, and no evaluation was made on the optical characteristics of the obtained single crystal or the like.

Further, in Japanese Unexamined Patent Publication No. 11(1999)-147757, a light-transmissive ceramic material represented by the general formula M₃Al₅O₁₂ (in the formula, M is at least one of Er, Tm, Ho, Dy, Lu and Tb) is disclosed. In Japanese Unexamined Patent Publication No. 11(1999)-147757, use of the light-transmissive ceramic material as the material for the luminescent tube of a metal halide lamp is described. In Japanese Unexamined Patent Publication No. 11(1999)-147757, there are descriptions that all of ions at 8-coordination sites consist of only rare-earth elements (only Er, Tm, Ho, Dy, Lu and Tb). However, the concentration of Tb in the ceramic material is not specified. In Japanese Unexamined Patent Publication No. 11(1999)-147757, only Tb:YAG having a Tb concentration C(Tb/A) of 100 mol % was actually prepared.

Tb:YAG may be utilized as a phosphor for a white light emitting diode (hereinafter, referred to as a white LED), a laser medium of a solid-state laser device, or the like.

Further, as a method for obtaining a white LED having excellent color rendition, which functions as an index of natural light emission, and that enables easy adjustment of the tone of color, a method for obtaining white light by additive color mixture of blue, green and red, which are three primary colors of light, is considered. Further, research is widely conducted on phosphors that efficiently convert light having a wavelength within the range of ultraviolet to blue into light of each of blue, green and red. Tb:YAG is considered as one of green phosphors having high efficiency However, there has been no reports that Tb:YAG was actually considered as a green phosphor for a white LED.

Further, European Patent Application Publication No. 1162705 discloses a laser diode excitation solid-state laser device including a solid-state laser medium containing a rare-earth-ion-doped luminescent compound. The solid-state laser device also includes a laser diode that emits light for exciting the solid-state laser medium, the light having an oscillation wavelength within the range of 340 to 640 nm. Further, there are descriptions that the solid-state laser device can emit laser light having a wavelength within the range of visible light of 400 to 700 nm. In European Patent Application Publication No. 1162705, Tb is specified as an example of a rare earth ion with which the compound is doped. As a parent compound doped with Tb, only fluorides, such as CaF₂ and LiYF₄, are specified as examples, but no oxides, such as YAG, are specified. Further, the preferable amount of Tb for a solid-state laser medium is not described.

As described above, the feature that Tb:YAG can be prepared within the range of the Tb concentration C(Tb/A) of 0 to 100 mol % has been disclosed. However, since it has been conventionally believed that the preferable concentration of Tb C(Tb/A) is less than or equal to 10 mol %, the relationship between the concentration of Tb and the luminescence characteristic and optimization of the concentration of Tb have been considered only for the case in which the concentration of Tb C(Tb/A) is 10 mol % or less. In other words, no research has been conducted on a case in which the Tb concentration C(Tb/A) exceeds 10 mol %.

It can be considered that conventionally, evaluation of the luminescence characteristic of Tb:YAG and optimization of the concentration of Tb in Tb:YAG were substantially performed by using electron beam excitation and deep ultraviolet light having a wavelength of less than or equal to 280 nm as excitation light.

Further, there have been substantially no detailed reports on luminescence characteristics or the like of Tb-doped luminescent compounds other than Tb:YAG.

When a Tb-doped luminescent compound is intended to be used as a phosphor for a white LED and a solid-state laser medium, light within the range of ultraviolet to visible light wavelength region is preferable as excitation light. This excitation condition is different from excitation conditions that have been conventionally adopted in evaluation. Since the luminescence characteristic changes depending on the excitation condition, it is necessary to evaluate the luminescence characteristic in an excitation condition that is appropriate for the use of the Tb-doped luminescent compound. However, conventionally, substantially no research was even conducted on such use of the Tb-doped luminescent compound. Further, no evaluation was made on the use of the Tb-doped luminescent compound as a phosphor for a white LED and a solid-state laser medium.

### SUMMARY OF THE INVENTION

In view of the foregoing circumstances, it is an object of the present invention to optimize the concentration of Tb (Tb concentration) in a Tb-doped luminescent compound in an appropriate excitation condition when the Tb-doped luminescent compound is used as a phosphor for a white light emitting diode, a laser medium of a solid-state laser device or the like. In the present invention, the concentration of Tb is optimized by identifying the relationship between the concentration of Tb and the luminescence characteristic in the appropriate excitation condition. Further, it is an object of the present invention to provide a Tb-doped luminescent compound that has an excellent luminescence characteristic as a phosphor for a white light emitting diode, a laser medium for a solid-state laser device or the like by optimizing the concentration of Tb in the excitation condition. It is still another object of the present invention to provide a luminescent composition using the Tb-doped luminescent compound, a luminescent body using the Tb-doped luminescent compound, a light emitting device using the luminescent body and a solid-state laser device using the luminescent body.

A Tb-doped luminescent compound of the present invention is a Tb-doped luminescent compound containing Tb and at least two kinds of metal elements other than Tb, and emitting light by irradiation with excitation light, wherein the concentration of Tb with respect to the total number of moles of all of the metal elements including Tb is within the range of more than 3.75 mol % to 20.625 mol % inclusive.

As the Tb-doped luminescent compound of the present invention, a Tb-doped luminescent compound that has garnet-type crystal structure is appropriate. As an example of such a compound, there is a garnet-type compound represented by the following general formula:

(A(III)₁₋ₓTbₓ)₃B(III)₂C(III)₃O₁₂, where each of the Roman numerals in the parentheses represents the valence of an ion, A is at least one kind of element selected from the group consisting of Sc, Y, In, La, Ce, Pr, Nd, Sm, Gd, Dy, Ho, Er, Tm, Yb and Lu, B is at least one kind of element selected from the group consisting of Al, Sc, Cr, Ga, In, Sm, Eu, Gd, Dy, Ho, Er, Tm, Yb and Lu, C is at least one kind of element selected from the group consisting of Al and Ga, O is an oxygen atom, and 0.1<x≦0.55.

In the specification of the present application, “the concentration of Tb with respect to the total number of moles of all of the metal elements including Tb” is represented by parameter C(Tb/all).

In the garnet-type compound represented by the above general formula, the value of x may optionally satisfy 0.2≦x≦0.4.

As the Tb-doped luminescent compound of the present invention, there is a compound represented by the above general formula, wherein A(III) is Y, B(III) is Al, and C(III) is Al.

A luminescent composition of the present invention is a luminescent composition containing the Tb-doped luminescent compound of the present invention.

A luminescent body of the present invention is a luminescent body having a luminescence characteristic, the luminescent body emitting light by irradiation with excitation light, the luminescent body further having a predetermined shape, wherein the luminescent body contains the Tb-doped luminescent compound of the present invention.

In the luminescent body of the present invention, if the Tb-doped luminescent compound is a laser material, which emits laser light by being excited by excitation light, the luminescent body of the present invention may be used as a solid-state laser medium. According, it is possible to provide the following solid-state laser device of the present invention.

A first solid-state laser device of the present invention is a solid-state laser device comprising:

a solid-state laser medium; and

an excitation light source for irradiating the solid-state laser medium with excitation light, wherein the solid-state laser medium is the luminescent body of the present invention.

Further, a second solid-state laser device of the present invention is a solid-state laser device comprising:

a solid-state laser medium; and

an excitation light source for irradiating the solid-state laser medium with excitation light, wherein the solid-state laser medium contains a Tb-doped oxide.

Further, a light emitting device of the present invention is a light emitting device comprising:

the luminescent body of the present invention; and

an excitation light source for irradiating the luminescent body with excitation light.

The inventors of the present invention have identified the relationship between the Tb concentration in a Tb-doped luminescent compound and the luminescence characteristic of the compound and the optimum Tb concentration for a case in which light within the range of ultraviolet light to visible light wavelength region is used as excitation light. Conventionally, use of such light as excitation light has not been reported. The inventors of the present invention have found that in a Tb-doped luminescent compound, the intensity of luminescence is high when the Tb concentration C(Tb/all) with respect to the total number of moles of all of the metal elements including Tb is within the range of more than 3.75 mol % to 20.625 mol % inclusive.

In the present invention, a Tb-doped luminescent compound that has an excellent luminescence characteristic has been obtained by optimizing the concentration of Tb in the Tb-doped luminescent compound. Therefore, if the Tb-doped luminescent compound of the present invention is used, it is possible to provide a luminescent body that has high luminescence efficiency.

Therefore, it is possible to provide a light emitting device and a solid-state laser device that emit high intensity light, and which have high efficiency.

### BRIEF DESCRIPTION OF THE DRAWINGS

FIG. 1A is a diagram illustrating an example of a cross-section of a polycrystal sintered body;

FIG. 1B is a diagram illustrating an example of a cross-section of a polycrystal sintered body (FIG. 1B is a so-called image view);

FIG. 2A is a diagram illustrating a particle that has a truncated octahedral shape;

FIG. 2B is a diagram illustrating a particle that has a rhombic dodecahedral shape;

FIG. 3A is a diagram illustrating the manner in which particles that have truncated octahedral shapes fill the space;

FIG. 3B is a diagram illustrating the manner in which particles that have truncated octahedral shapes fill the space;

FIG. 3C is a diagram illustrating the manner in which particles that have truncated octahedral shapes fill the space;

FIG. 3D is a diagram illustrating the manner in which particles that have truncated octahedral shapes fill the space;

FIG. 4 is a diagram illustrating how the shape of a particle changes as reaction time passes when a garnet-type compound is hydrothermally synthesized;

FIG. 5 is a diagram illustrating the structure of a solid-state laser device (visible light emission) according to an embodiment of the present invention;

FIG. 6 is a diagram illustrating the structure of a solid-state laser device (ultraviolet light emission) according to an embodiment of the present invention;

FIG. 7A is a diagram illustrating an example of design modification of the solid-state laser device;

FIG. 7B is a diagram illustrating an example of design modification of the solid-state laser device;

FIG. 8A is a diagram illustrating the structure of a light emitting device according to an embodiment of the present invention;

FIG. 8B is a diagram illustrating the structure of a light emitting device according to an embodiment of the present invention;

FIG. 9A is a diagram illustrating a result obtained by measuring X-ray diffraction of powder of Example 1;

FIG. 9B is a diagram illustrating a result obtained by measuring X-ray diffraction of powder of Example 1;

FIG. 10 is a diagram illustrating a result obtained by measuring X-ray diffraction of powder of Example 1;

FIG. 11 is a diagram illustrating a relationship between the concentration of Tb and lattice constants in Example 1;

FIG. 12A is a diagram illustrating a luminescence spectrum of 1.0% Tb:YAG (Sample 2);

FIG. 12B is a diagram illustrating an excitation spectrum;

FIG. 13 is a diagram illustrating a result obtained by measuring the fluorescence lifetime of 1.0% Tb:YAG (Sample 2);

FIG. 14 is a diagram illustrating a relationship between the concentration of Tb and the intensity of luminescence at a wavelength of 542 nm when an excitation wavelength is 377 nm; and

FIG. 15 is a diagram illustrating a relationship between the concentration of Tb and the fluorescence lifetime in Example 1.

### DESCRIPTION OF THE PREFERRED EMBODIMENTS

Hereinafter, the present invention will be described in detail.

### “Tb-Doped Luminescent Compound”

The inventors of the present invention conducted research on the relationship between the concentration of Tb in a Tb-doped luminescent compound and the luminescence characteristic of the compound (hereinafter, the concentration of Tb is also referred to as a Tb concentration). Consequently, they have found that it is possible to obtain high luminescence intensity when the Tb concentration C(Tb/all) with respect to the total number of moles of all of metal elements (including Tb) contained in the luminescent compound is within the range of more than 3.75 mol % to 20.625 mol % inclusive (please refer to FIG. 14 of Example 1. A Tb-doped luminescent compound described in Example 1 has garnet-type crystal structure. In FIG. 14, the concentration of Tb is indicated by a Tb concentration C(Tb/A), which is the concentration of Tb in A-sites (including Tb), which are eight-coordination sites of the garnet structure. The Tb concentration C(Tb/all) within the range of more than 3.75 mol % to 20.625 mol % inclusive corresponds to a Tb concentration C(Tb/A) within the range of more than 10.0 mol % to 55.0 mol % inclusive in FIG. 14).

Specifically, the Tb-doped luminescent compound of the present invention is a Tb-doped luminescent compound containing Tb and at least two kinds of metal elements other than Tb. The Tb-doped luminescent compound emits light by irradiation with excitation light. The Tb-doped luminescent compound is characterized in that the Tb concentration C(Tb/all) with respect to the total number of moles of all of the metal elements (including Tb) contained in the luminescent compound is within the range of more than 3.75 mol % to 20.625 mol % inclusive.

The Tb-doped luminescent compound of the present invention may have single crystal structure or polycrystalline structure. Further, the Tb-doped luminescent compound of the present invention may contain unavoidable impurities.

In the Tb-doped luminescent compound of the present invention, it is possible to obtain an excellent luminescence characteristic without co-doping the compound with an element other than Tb as luminescent center ions. Therefore, the Tb-doped luminescent compound of the present invention may have structure that substantially contains only Tb as luminescent center ions. Here, the expression “substantially contains only Tb as luminescent center ions” means that only Tb is contained as the luminescent center ions in the Tb-doped luminescent compound excluding unavoidable impurities. However, if necessary, the compound may be co-doped with an element other than Tb as the luminescent center ions.

It is desirable that the Tb-doped luminescent compound of the present invention has garnet-type crystal structure. The Tb-doped luminescent compound of the present invention will be described using garnet-type crystal structure as an example.

When a Tb-doped luminescent compound has garnet-type crystal structure, Tb normally substitutes eight-coordination sites (normally, A-sites) of garnet structure through solid solution formation. Therefore, the concentration of Tb in the garnet structure is basically represented by the Tb concentration C(Tb/A) in 8-coordination sites (including Tb).

As described above, the luminescent compound of the present invention is characterized in that the Tb concentration C(Tb/all) with respect to the total number of moles of all of the metal elements (including Tb) contained in the luminescent compound is within the range of more than 3.75 mol % to 20.625 mol % inclusive. This range corresponds to the range of the Tb concentration C(Tb/A) in eight-coordination sites of more than 10.0 mol % to 55.0 mol % inclusive.

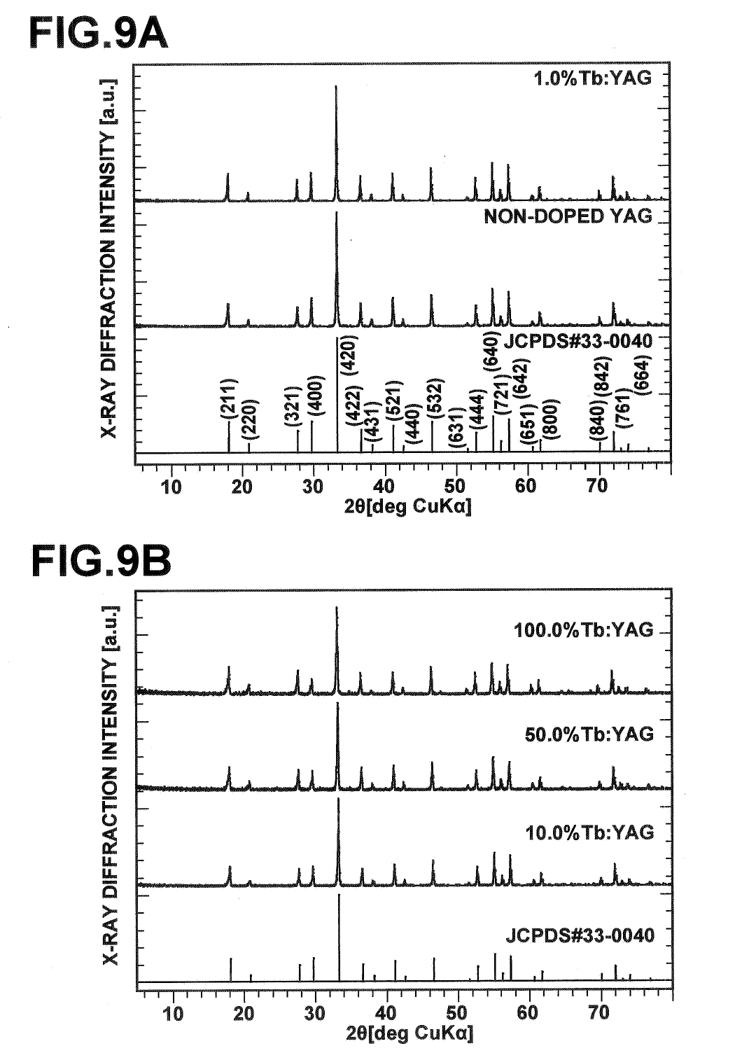

The garnet-type Tb-doped luminescent compound of the present invention may have single phase structure in the entire range of the Tb concentration C(Tb/A) of 0 to 100 mol % (please refer to FIGS. 9A and 9B of Example 1). However, the garnet-type Tb-doped luminescent compound may include a heterogeneous phase as long as the characteristic of the compound is not affected.

As an example of the garnet-type Tb-doped luminescent compound of the present invention, there is a garnet-type compound represented by the following general formula:

(A(III)₁₋ₓTbₓ)₃B(III)₂C(III)₃O₁₂,

(In the formula, each of the Roman numerals in the parentheses represents the valence of an ion,

A: at least one kind of element selected from the group consisting of Sc, Y, In, La, Ce, Pr, Nd, Sm, Gd, Dy, Ho, Er, Tm, Yb and Lu,

B: at least one kind of element selected from the group consisting of Al, Sc, Cr, Ga, In, Sm, Eu, Gd, Dy, Ho, Er, Tm, Yb and Lu,

C: at least one kind of element selected from the group consisting of Al and Ga,

O: an oxygen atom, and

0.1<x≦0.55.)

In the formula, x is a numerical value representing the number of moles of Tb, and the value of x is determined by the concentration of Tb. Specifically, the range of the Tb concentration C(Tb/A) of more than 10.0 mol % to 55.0 mol % inclusive corresponds to 0.1<x≦0.55.

In the garnet-type Tb-doped luminescent compound of the present invention represented by the above general formula, it is desirable that the value of x satisfies 0.2≦x≦0.4 (corresponding to the range of the Tb concentration C(Tb/A) of 20.0 mol % to 40.0 mol % both inclusive). Further, as an example of the garnet-type Tb-doped luminescent compound of the present invention, represented by the above general formula, there is a garnet-type Tb-doped luminescent compound in which A(III) is Y, B(III) is Al, and C(III) is Al. In this case, a parent garnet-type compound is Y₃Al₅O₁₂(YAG).

In the present invention, a relationship between the concentration of Tb and a luminescence characteristic and an appropriate value of the concentration of Tb have been identified for the case in which light within the range of ultraviolet light to visible light wavelength region is used as excitation light. Conventionally, there was no report about the relationship between the concentration of Tb and a luminescence characteristic and the appropriate value of the concentration of Tb for the case in which such light was used as excitation light. Conventionally, the luminescence characteristic of a Tb-doped luminescent compound was considered only for a case in which electron beam excitation or deep ultraviolet light having a wavelength of less than or equal to 280 nm was used as excitation light, and the luminescence characteristic of the Tb-doped luminescent compound was considered for the case in which the Tb concentration C(Tb/A) was less than or equal to 10 mol %, which was supposed to be an appropriate range of the concentration of Tb. In other words, no evaluation was made on the luminescence characteristic and the like for the case in which the Tb concentration C(Tb/A) exceeds 10 mol %.

In the present invention, the luminescence characteristic of Tb:YAG has been evaluated for the range of the Tb concentration C(Tb/A) of 0 to 100 mol %. As the result of the evaluation, the inventors of the present invention have found that high intensity luminescence can be obtained within the range of the Tb concentration C(Tb/A) of more than 10.0 mol % to 55.0 mol % inclusive (=the range of the Tb concentration C(Tb/all) of more than 3.75 mol % to 20.625 mol % inclusive).

As a parent compound that has structure other than the garnet structure but that can be applied to the present invention, there are following parent compounds M1 through M8.

(M1) Parent Compound: C-rare-earth-type compound represented by the following general formula:

R(III)₂O₃

(in the formula, the Roman numeral in the parentheses represents the valence of an ion, R is at least one kind of element selected from the group consisting of Y and trivalent rare earth elements (La, Ce, Pr, Nd, Sm, Eu, Gd, Dy, Ho, Er, Tm, Yb and Lu), and O is an oxygen atom).

(M2) Parent Compound: perovskite-type compound represented by the following general formula:

A(II)B(IV) O₃

(in the formula, each of the Roman numerals in the parentheses represents the valence of an ion, A is at least one kind of element selected from the group consisting of Ba, Sr, Ca, Mg and Pb, and B is at least one kind of element selected from the group consisting of Ti, Zr, Hf, Th, Sn and Si, and O is an oxygen atom).

(M3) Parent Compound: perovskite-type compound represented by the following general formula:

A(I)B(V) O₃

(in the formula, each of the Roman numerals in the parentheses represents the valence of an ion, A is at least one kind of element selected from the group consisting of Li, Na and K, and B is at least one kind of element selected from the group consisting of V, Nb and Ta, and O is an oxygen atom).

(M4) Parent Compound: perovskite-type compound represented by the following general formula:

A(II)B1(II)_{1/2}B2(VI)_{1/2}O₃

(in the formula, each of the Roman numerals in the parentheses represents the valence of an ion, A is at least one kind of element of which the total valence of ions is two, B1 is at least one kind of element selected from the group consisting of Fe, Cr, Co and Mg, B2 is at least one kind of element selected from the group consisting of W, Mo, Re and Os, and O is an oxygen atom).

(M5) Parent Compound: perovskite-type compound represented by the following general formula:

A(II)B1(II)_{2/3}B2 (VI)_{1/3}O₃

(in the formula, each of the Roman numerals in the parentheses represents the valence of an ion, A is at least one kind of element of which the total valences of ions is two, B1 is at least one kind of element selected from the group consisting of In, Sc, Y, Cr, Fe and trivalent rare earth elements (La, Ce, Pr, Nd, Sm, Eu, Gd, Tb, Dy, Ho, Er, Tm, Yb and Lu), B2 is at least one kind of element selected from the group consisting of W, Mo and Re, and O is an oxygen atom)

(M6) Parent Compound: perovskite-type compound represented by the following general formula:

A(II)B1(III)_{1/2}B2 (V)_{1/2}O₃

(in the formula, each of the Roman numerals in the parentheses represents the valence of an ion, A is an element at an A-site, and A is at least one kind of element of which the total valence of ions is two, B1 is at least one kind of element selected from the group consisting of Sc, Fe, Bi, Mn, Cr, In, Ga, Ca and trivalent rare earth elements (La, Ce, Pr, Nd, Sm, Eu, Gd, Tb, Dy, Ho, Er, Tm, Yb and Lu), B2 is at least one kind of element selected from the group consisting of Nb, Ta, Os and Sb, and O is an oxygen atom).

(M7) Parent Compound: perovskite-type compound represented by the following general formula:

A(II)B1(II)_{1/3}B2(V)_{2/3}O₃

(in the formula, each of the Roman numerals in the parentheses represents the valence of an ion, A is at least one kind of element of which the total valence of ions is two, B1 is at least one kind of element selected from the group consisting of Mg, Co, Ni, Zn, Fe, Pb, Sr and Ca, B2 is at least one kind of element selected from the group consisting of Nb and Ta, and 0 is an oxygen atom).

### (M8) Parent Compound: compound represented by the following general formula (referred to as a perovskite-type compound or a GdFeO₃-type compound):

A(III)B(III)O₃

(in the formula, each of the Roman numerals in the parentheses represents the valence of an ion, A is at least one kind of element selected from the group consisting of Y, La, Ce, Pr, Nd, Sm, Eu, Gd and Bi, and B is at least one kind of element selected from the group consisting of Al, Sc, Ga, Cr, V, Fe, Co and Y, and O is an oxygen atom).

As a parent compound that is not a garnet-type compound but that can be applied to the present invention, a compound, such as a fluoride (CaF₂, LiYF₄, or the like), may be used instead of the aforementioned oxides.

In the present invention, a Tb-doped luminescent compound that has an excellent luminescence characteristic has been obtained for the case in which the excitation light is light within the range of ultraviolet light to visible light wavelength region by optimizing the concentration of Tb.

The Tb-doped luminescent compound of the present invention is a laser material, which emits light by being excited by excitation light. The Tb-doped luminescent compound of the present invention may be used for various purposes, such as a solid-state laser medium.

Further, it is possible to excite the Tb-doped luminescent compound of the present invention using an existing light source (for example, GaN-based laser diode or the like) that emits light within the range of ultraviolet light to visible light wavelength region. It is possible to increase the Tb concentration of the Tb-doped luminescent compound of the present invention to a high level. Further, even if the compound is doped with Tb at a high concentration, attenuation of the intensity of luminescence is small (concentration quenching is small). Further, sufficient phosphor lifetime is obtained. Therefore, the Tb-doped luminescent compound of the present invention can be used as a solid-state laser medium or the like (please refer to Example 1).

### “Luminescent Composition of the Present Invention”

A luminescent composition of the present invention is characterized by containing the Tb-doped luminescent compound of the present invention.

The luminescent composition of the present invention may contain an arbitrary element (for example, resin or the like) other than the compound of the present invention, if necessary.

### “Luminescent Body”

A luminescent body of the present invention has a luminescence characteristic and emits light by irradiation with excitation light. Further, the luminescent body has a predetermined shape. The luminescent body is characterized by containing the Tb-doped luminescent compound of the present invention.

The luminescent body of the present invention may be used as a solid-state laser medium, a phosphor for a white light emitting diode (LED) or the like.

In an embodiment of the present invention, the luminescent body of the present invention is a polycrystal sintered body. The polycrystal sintered body is obtained by forming at least one kind of raw material powder containing the composition elements of the Tb-doped luminescent compound of the present invention into a powder-molded body having a predetermined shape and by sintering the formed powder-molded body. In the present invention, a highly transparent polycrystal sintered body (transparent ceramics), which can be used as a solid-state laser medium or the like, can be produced by optimizing the production process or the like.

The polycrystal sintered body may be used as a solid-state laser medium or the like after processing the polycrystal sintered body, if necessary. In the processing, the polycrystal sintered body may be formed into a desirable shape (prism or the like) by cutting or the like, or the end of the polycrystal sintered body may be polished (laser-grade optical polishing or the like).

The polycrystal sintered body may be produced, for example, by preparing powder for sintering containing the composition elements of the compound of the present invention by using an ordinary solid phase reaction ceramics method, by obtaining a powder-molded body by performing compression molding or the like on the powder for sintering, and by sintering the powder-molded body (please refer to Examples 1 and 2 for the details of process examples). If necessary, a sintering aid (additive), such as SiO₂, may be used and vacuum sintering may be performed. Then, it is possible to produce a polycrystal sintered body (transparent ceramics), which has an excellent transparency characteristic. When the transparency characteristic of the polycrystal sintered body is taken into consideration, less sintering aid (additive) should be used.

The powder for sintering may be prepared by using a method other than the ordinary solid phase reaction ceramics method. For example, the powder for sintering containing the composition elements of the compound of the present invention may be prepared by using other methods, such as a hydrothermal synthesis method and an alkoxide emulsion method, for example.

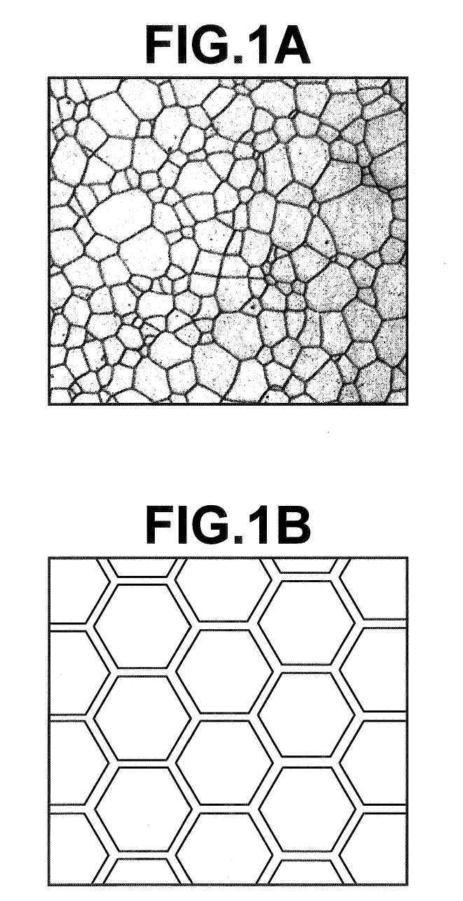

In the powder for sintering obtained by using the ordinary solid phase reaction ceramics method, the sizes and the shapes of particles are not uniform (the sizes and the shapes are random). FIG. 1A shows one of examples of a photograph of a cross-section of a polycrystal sintered body obtained by sintering the powder for sintering. The photograph is a photograph obtained using a scanning electron microscope (SEM). FIG. 1A shows the state in which the sizes and the shapes of the crystal grains are not uniform (they are random).

In contrast, if the hydrothermal synthesis method, the alkoxide emulsion method or the like is used, it is possible to prepare powder for sintering formed by a multiplicity of particles that have substantially the same sizes and shapes. If sintering is performed using such powder for sintering, it is possible to produce a polycrystal sintered body formed by an aggregate of a multiplicity of crystal grains that have substantially the same sizes and shapes. In such a case, since the sizes of the crystal grains and the shapes of the crystal grains are highly uniform, a homogeneous polycrystal sintered body (transparent ceramics) that has an excellent transparency characteristic can be obtained.

If the alkoxide emulsion method is used, it is possible to prepare powder for sintering, for example, formed by a multiplicity of particles that have substantially the same sizes and substantially spherical shapes (particle diameter: 0.2 to 0.8 μm approximately, for example) (please refer to Example 3).

If the hydrothermal synthesis method is used, it is possible to prepare powder for sintering formed by a multiplicity of particles that have substantially the same sizes and shapes, and which have polyhedral shapes such that the particles can solely fill the entire space of the polycrystal sintered body substantially without any empty space therebetween (particle diameter: a few microns to 20 μm approximately, for example) (please refer to Example 4.) If sintering is performed using this powder for sintering, each of the particles forms a crystal grain. Accordingly, it is possible to produce a polycrystal sintered body formed by an aggregate of a multiplicity of crystal grains that have substantially the same sizes and shapes, and the shapes of the crystal grains are polyhedral shapes such that the particles can solely fill the entire space of the polycrystal sintered body substantially without any empty space therebetween. If this method is used, it is possible to obtain a homogeneous polycrystal sintered body (transparent ceramics), in which the proportion of particle boundaries is low, and which has a high space filling rate and an excellent transparency characteristic.

In the specification of the present application, the expression “a multiplicity of crystal grains have substantially the same sizes” refers to that the grain diameters of the multiplicity of crystal grains fall within the range of ±5% of the mean grain diameter. The phrase “mean particle diameter” refers to the arithmetic mean value of the diameters (circle/sphere converted) of the crystal grains.

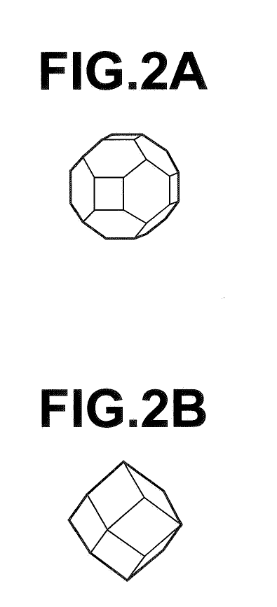

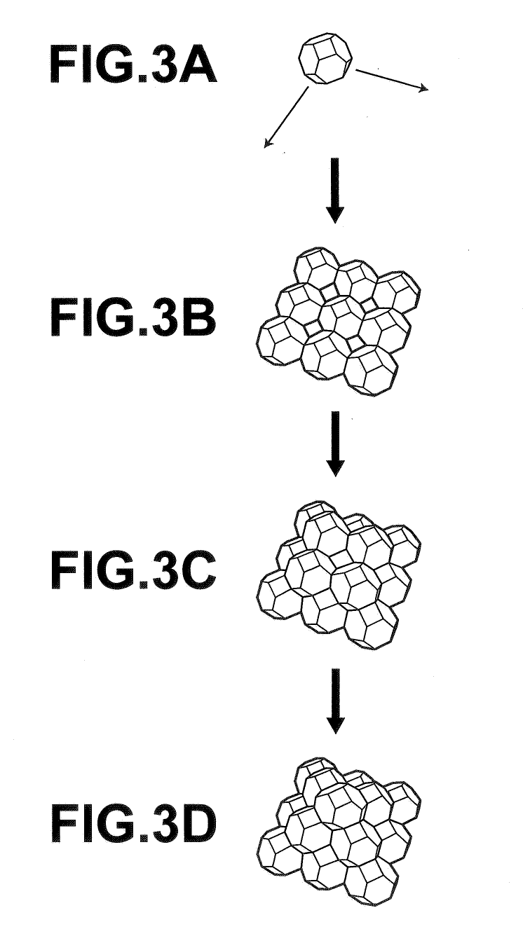

Examples of the polyhedrons that can solely fill the space substantially without any empty space include a cube, a truncated octahedron, as illustrated in FIG. 2A, and a rhombic dodecahedron, as illustrated in FIG. 2B. FIGS. 3A, 3B, 3C, and 3D are diagrams illustrating the manner in which the particles having truncated octahedral shapes fill the space step by step. FIGS. 3A, 3B, 3C, and 3D illustrate the feature that the particles can solely fill the entire space substantially without any empty space therebetween.

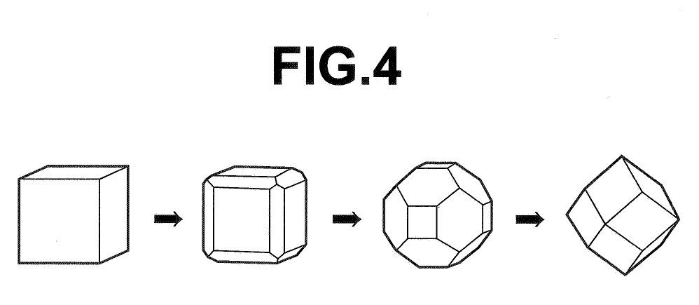

When a garnet-type compound is hydrothermally synthesized, the shapes of the synthesized particles vary depending on reaction conditions, such as reaction time. As illustrated in FIG. 4, if the conditions other than the reaction time are the same, the shape of an obtained particle sequentially changes as time passes. Specifically, the shape of the obtained particle is changed from a cubic shape to a truncated octahedral shape, and to a rhombic dodecahedral shape.

When the garnet-type compound is hydrothermally synthesized, particles that have truncated octahedral shapes or rhombic dodecahedral shapes tend to be formed. Therefore, if powder for sintering is prepared by using the hydrothermal synthesis method and sintering is performed using the powder for sintering, it is possible to relatively easily obtain a polycrystal sintered body formed by an aggregate of a multiplicity of crystal grains that have substantially the same sizes and shapes, the particle shapes being truncated octahedral shapes or rhombic dodecahedral shapes.

FIG. 1B is a diagram illustrating a so-called image view of a cross-section of a polycrystal sintered body, in which the shapes of the crystal grains are truncated octahedral shapes, and the crystal grains have uniform sizes and shapes. In FIG. 1B, the cross-section is schematically illustrated so that the structure can be easily compared with the random structure illustrated in FIG. 1A. However, in an actual polycrystal sintered body, crystal grains that have truncated octahedral shapes are three-dimensionally combined, as illustrated in FIGS. 3A through 3D. Therefore, there is not possibility that equilateral octagonal shapes are regularly formed on the same cross-sectional plane as illustrated in FIG. 1B. Further, the scale of FIG. 1B is different from that of FIG. 1A. In FIG. 1B, particle boundaries are enlarged, but the actual sizes of the particle boundaries in FIG. 1B are substantially the same as those of the particle boundaries in. FIG. 1A.

Besides the polycrystal sintered body, the luminescent body according to the embodiment of the present invention may be a molded body, in which a powder-form compound (ground particles of the polycrystal sintered body or the like) of the present invention is dispersed in a solid-state medium, such as a light transmissive resin binder, silica gel or glass. As the light transmissive resin binder, there are (meth) acrylic-based resin, epoxy resin, urea resin, silicone resin and the like.

### “First Solid-State Laser Device”

The first solid-state laser device of the present invention is a solid-state laser device comprising:

A solid-state laser medium; and

an excitation light source for irradiating the solid-state laser medium with excitation light, wherein the solid-state laser medium is the luminescent body of the present invention.

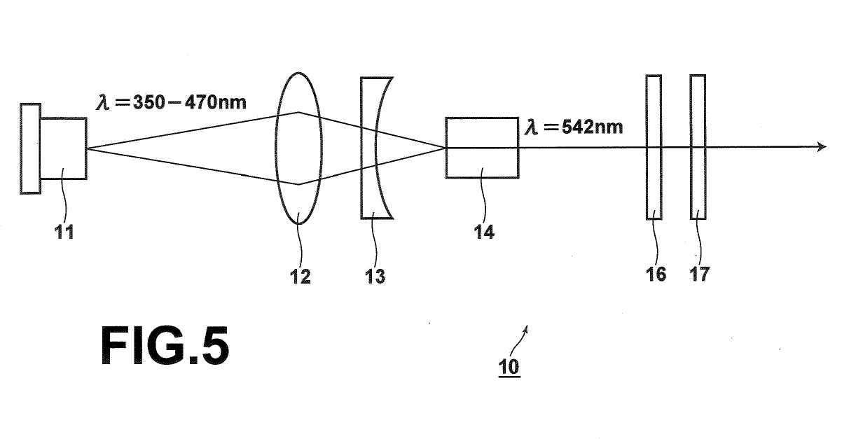

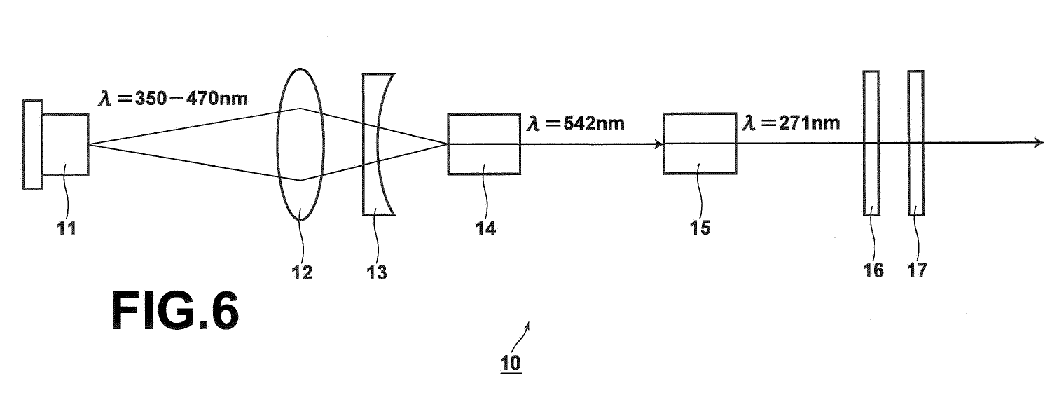

An embodiment of the solid-state laser device of the present invention will be described with reference to FIGS. 5 and 6. Here, a solid-state laser device of an end-surface excitation type will be used as an example.

A solid-state laser device 10 according to an embodiment of the present invention is a laser diode excitation solid-state laser device including a solid-state laser medium 14 and a laser diode 11, which is an excitation light source. The solid-state laser medium 14 is formed by the luminescent body of the present invention, which emits laser light by being excited by excitation light. The laser diode 11 irradiates the solid-state laser medium 14 with excitation light.

A condensing lens 12 is placed between the laser diode 11 and the solid-state laser medium 14. Further, an output mirror 17 that selectively transmits output light is placed in a later stage after the solid-state laser medium 14. The solid-state laser medium 14 is placed between a pair of resonator mirrors 13 and 16.

In the embodiment of the present invention, the solid-state laser medium 14 is formed by a polycrystal sintered body (one of Examples 1 to 4) of Tb:YAG, which has an excellent transparency characteristic. The Tb concentration C(Tb/all) in Tb:YAG is within the range of more than 10.0 mol % to 55.0 mol % inclusive, which is provided in the present invention. Optionally, the Tb concentration C(Tb/all) may be within the range of 20.0 mol % to 40.0 mol % both inclusive. Further, if necessary, the polycrystal sintered body may be processed into an appropriate shape by cutting or the like and end surface polishing (laser-grade optical polishing) maybe further performed on the polycrystal sintered body to form the solid-state laser medium 14.

The shape of the solid-state laser medium 14 is not particularly limited. The shape may be a cylindrical rod shape, a prismatic rod shape, a disk shape, a rectangular plate shape or the like.

Tb:YAG is excited by light having a wavelength within the range of 220 nm to 500 nm and emits fluorescence having a wavelength within the visible light wavelength region (400 nm to 700 nm). Therefore, the excitation light source should be selected based on the desirable wavelength of light to be emitted.

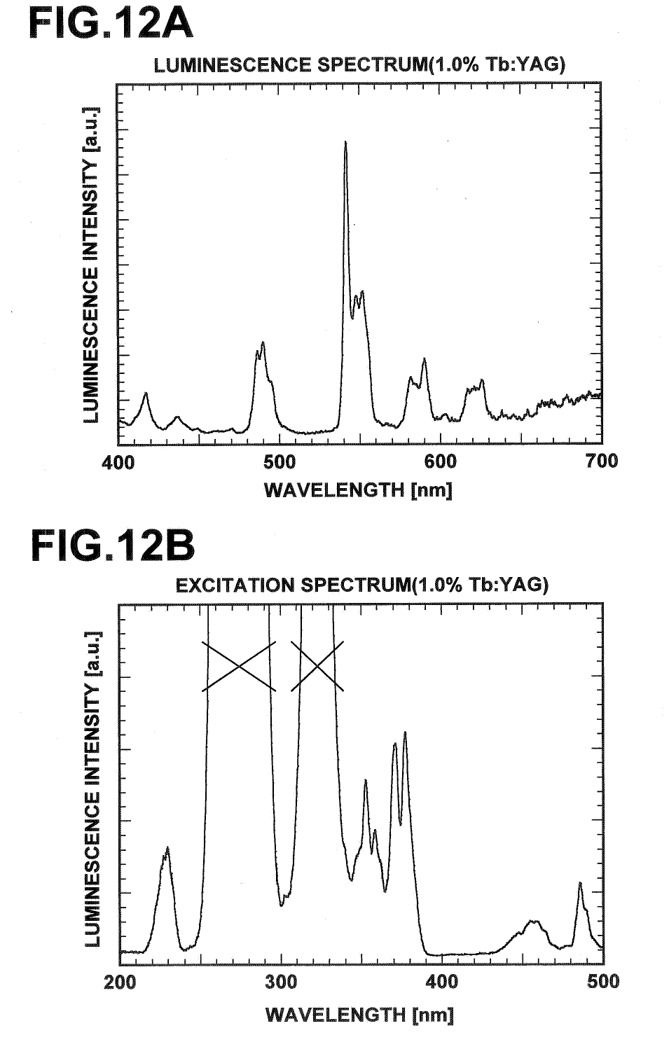

An excitation peak wavelength of Tb:YAG is, for example, 377 nm (please refer to FIG. 12B of Example 1). Therefore, as the laser diode 11, which is the excitation light source, a laser diode that has an oscillation peak wavelength within the range of 350 nm to 470 nm is appropriate. Optionally, the oscillation peak wavelength of the laser diode may within the range of 360 to 390 nm.

Specifically, as an example of the laser diode that has the oscillation peak wavelength within the range of 350 to 470 nm, there is a GaN-based laser diode including an active layer containing at least one kind of nitrogen-containing semiconductor compounds, such as GaN, AlGaN, InGaN, InAlGaN, InGaNAs and GaNAs. Optionally, as the active layer of the GaN-based laser diode, a multiple quantum well layer, such as AlN/AlGaN, AlGaN/GaN, InGaN/InGaN or InAlGaN/InAlGaN, or a quantum dot layer, such as AlGaN, GaN or InGaN, may be used. The oscillation wavelength of the GaN-based laser diode can be arbitrarily changed substantially within the range of 350 to 470 nm by designing the active layer or the like in an appropriate manner.

Examples of the laser diode that has an oscillation peak wavelength within the range of 350 nm to 470 nm are Group-II-to-Group-VI-compound-based laser diodes, such as a ZnO-based laser diode and a ZnSe-based laser diode.

The solid-state laser device 10 according to an embodiment of the present invention can emit light that has a wavelength within the range of 470 to 640 nm. The solid-state laser device 10 according to the embodiment of the present invention can emit light that has a wavelength of 542 nm within the range of visible light wavelength region (green) by being excited by ultraviolet light that has a wavelength of 377 nm, for example.

As illustrated in FIG. 6, if a wavelength conversion device 15, such as nonlinear optical crystal body, is placed between a pair of resonator mirrors 13 and 16, it is possible to emit ultraviolet light.

As the wavelength conversion device 15, an SHG crystal, such as a BBO crystal or a BIBO crystal, is used. The light having a wavelength of 542 nm emitted from the solid-state laser medium 14 is converted by the wavelength conversion device 15 into light having a shorter wavelength, namely into light having a wavelength within the range of 235 nm to 320 nm in the ultraviolet light wavelength region (for example light that has a wavelength of 271 nm). The wavelength conversion device 15 may be placed within a resonator structure formed by the pair of the resonator mirrors 13 and 16. Alternatively, the wavelength conversion device 15 may be placed on the outside of the resonator structure.

The solid-state laser device 10 according to the embodiment of the present invention is structured as described above.

In the solid-state laser device 10 according to the embodiment of the present invention, the solid-state laser medium 14 formed by a luminescent body containing the compound of the present invention, which emits laser light by being excited by excitation light, is used. Therefore, the solid-state laser device 10 has an excellent luminescence characteristic. Further, the solid-state laser device 10 can output highly bright laser light.

In a conventional solid-state laser device, a solid-state laser medium containing Nd:YAG or Nd:YVO₄ is excited by a GaAs-based semiconductor laser having an oscillation peak wavelength of 808 nm to cause the solid-state laser medium to emit light having a wavelength of 1064 nm, for example. Then, a first wavelength conversion device (SHG crystal) performs wavelength conversion on the light emitted from the solid-state laser medium to obtain visible light that has a wavelength of 532 nm. Further, if ultraviolet light needs to be obtained, a second wavelength conversion device (THG or FHG crystal) performs wavelength conversion on the light having the wavelength of 532 nm to convert the light into light having a wavelength of 355 nm or 266 nm. In other words, two steps of wavelength conversion are performed to obtain ultraviolet light. Further, the energy conversion efficiency of a nonlinear crystal, which is used as the wavelength conversion device, is low. Therefore, in the solid-state laser device that is structured as described above, there is a problem that the efficiency must be improved.

As illustrated in FIG. 5, the solid-state laser device 10 according to the embodiment of the present invention can output light that has a wavelength of 542 nm in a visible light wavelength region, the light being emitted from the solid-state laser medium 14, without providing the wavelength conversion device 15. Further, as illustrated in FIG. 6, even when ultraviolet light needs to be obtained, only one time of wavelength conversion is necessary. Therefore, the structure of the solid-state laser device 10 according to the embodiment of the present invention is simpler than that of the conventional solid-state laser device. Further, it is possible to reduce the size of the device. The solid-state laser device 10 according to the embodiment of the present invention has high light utilization efficiency. Further, the solid-state laser device 10 can output light within the range of ultraviolet light to visible light wavelength region.

Tb:YAG has a plurality of oscillation peak wavelengths. Therefore, the wave length of laser light emitted from the solid-state laser medium 14 and the wavelength of light output from the solid-state laser device 10 may be appropriately changed to wavelengths other than the aforementioned wavelengths.

### (Design Modification Example)

The solid-state laser device of the present invention is not limited to the aforementioned embodiments, and various design modifications may be made to the structure of the device.

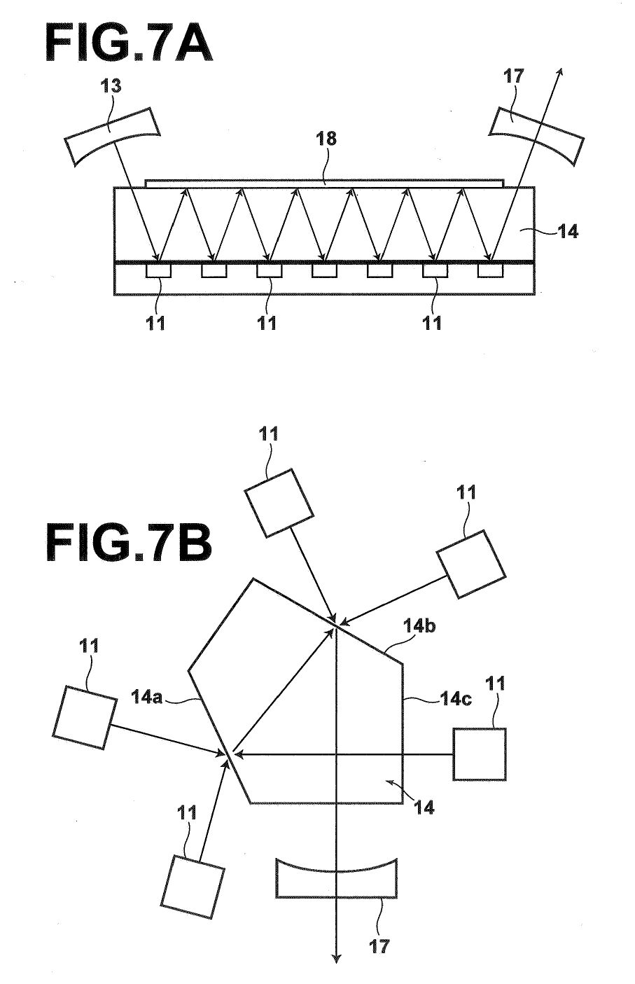

For example, as illustrated in FIG. 7A, a plane emission laser array, in which a plurality of laser diodes 11 are arranged in array form, is attached to one of the surfaces of the solid-state laser medium 14. Then, a reflection mirror 18 is placed on an opposite surface of the solid-state laser medium 14. Further, a reflection mirror 13 and an output mirror 17 are placed so that each of the reflection mirror 13 and the output mirror 17 faces either end of the solid-state laser medium 14 and that the two mirrors are substantially symmetrically positioned. Accordingly, a zigzag-path slab solid-state laser device can be structured. In this structure, a resonator structure is formed by the reflection mirror 13, the excitation light incident surface of the solid-state laser medium 14, the reflection mirror 18, and the output mirror 17.

The excitation light source may be a light source, in which the leading ends of a plurality of fiber lasers are arranged in array form instead of the plane emission laser array, in which a plurality of laser diodes 11 are arranged in array form.

As illustrated in FIG. 7B, the solid-state laser medium 14 may be formed by a polyhedral prism obtained by cutting, polishing or the like a polycrystal sintered body of Tb:YAG, which has an excellent transparency characteristic (one of Example 1 through 4). Further, the output mirror 17 may be placed so as to face one of the surfaces of the solid-state laser medium 14, and a plurality of semiconductor laser diodes 11 may be placed so as to face other surfaces of the solid-state laser medium 14. Accordingly, a laser diode excitation polyhedral prism-type solid-state laser device can be formed. In this example, each of excitation light incident surfaces 14a through 14c of the solid-state laser medium 14 is coated so that light within the excitation wavelength region is transmitted and light that has an output wavelength is reflected. In this structure, the solid-state laser medium 14 itself forms a resonator structure. As the excitation light source, a plurality of fiber lasers may be used instead of the plurality of semiconductor laser diodes 11.

In the solid-state laser devices illustrated in FIGS. 7A and 7B, it is possible to cause a single solid-state laser medium 14 to be excited by the plurality of laser diodes 11. Therefore, high output from the solid-state laser device is possible. In these examples, no wavelength conversion device is placed. However, a wavelength conversion device may be placed in a manner similar to the aforementioned embodiment, if necessary.

### “Second Solid-State Laser Device”

The structure of the solid-state laser device, in which the solid-state laser medium containing a Tb-doped oxide such as Tb:YAG is used, is novel regardless of the concentration of Tb.

Specifically, the second solid-state laser device of the present invention is a solid-state laser device including a solid-state laser medium and an excitation light source for irradiating the solid-state laser medium with excitation light. The second solid-state laser device is characterized in that the solid-state laser medium contains a Tb-doped oxide.

As the Tb-doped oxide, there is a garnet-type compound represented by the following general formula:

(A(III)₁₋ₓTbₓ)₃B(III)₂C(III)₃O₁₂, where each of the Roman numerals in the parentheses represents the valence of an ion, A is at least one kind of element selected from the group consisting of Sc, Y, In, La, Ce, Pr, Nd, Sm, Gd, Dy, Ho, Er, Tm, Yb and Lu, B is at least one kind of element selected from the group consisting of Al, Sc, Cr, Ga, In, Sm, Eu, Gd, Dy, Ho, Er, Tm, Yb and Lu, C is at least one kind of element selected from the group consisting of Al and Ga, O is an oxygen atom, and 0<x<1.

As the garnet-type Tb-doped compound represented by the above general formula, there is a compound in which A(III) is Y, B(III) is Al, and C(III) is Al. In this case, a parent garnet-type compound is Y₃Al₅O₁₂(YAG).

As described as the “Background Technique”,

European Patent Application Publication No. 1162705 discloses a laser diode excitation solid-state laser device including a solid-state laser medium containing a rare-earth-ion-doped luminescent compound and a laser diode that emits light for exciting the solid-state laser medium, the light having an oscillation wavelength within the range of 340 to 640 nm. Further, in European Patent Application Publication No. 1162705, Tb is specified as an example of the rare earth ion with which the compound is doped. As a parent compound that is doped with Tb, fluorides, such as CaF₂ and LiYF₄, are specified as examples. Therefore, a solid-state laser device in which a Tb-doped fluoride is used as the solid-state laser medium is well known.

However, in European Patent Application Publication No. 1162705, there are no descriptions of a compound other than fluorides as a parent compound that is doped with Tb. Since there are no such descriptions, it is considered that in European Patent Application Publication No. 1162705, oxides were not the objects of the research. Hence, the solid-state laser device in which Tb-doped oxide is used as a solid-state laser medium is novel.

As the parent compound that is doped with Tb, halides such as fluorides are chemically unstable. Further, the halides are not appropriate from the view point of production cost because it requires large production facilities. As the parent compound that is doped with Tb, an oxide such as a garnet-type compound is appropriate, because the oxide is chemically stable and the production cost is low.

### “Light Emitting Device”

A light emitting device of the present invention includes the luminescent body of the present invention and an excitation light source for irradiating the luminescent body with excitation light.

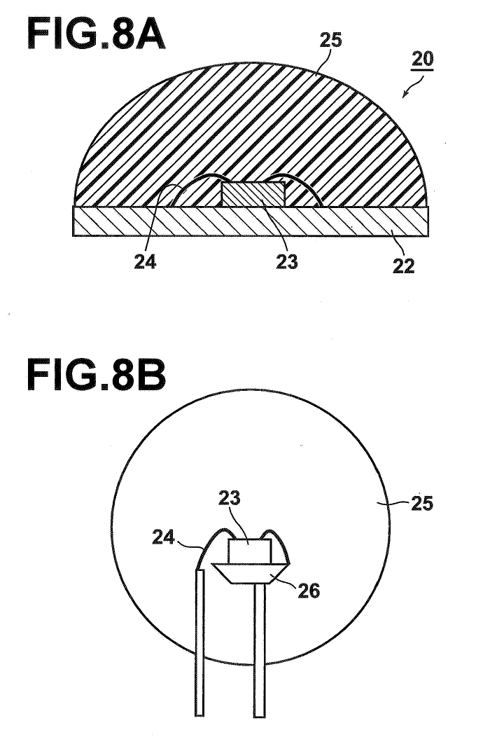

The structure of the light emitting device according to an embodiment of the present invention will be described with reference to FIG. 8A. FIG. 8A is a diagram illustrating a cross-section of the light emitting device in the thickness direction of a circuit substrate 22.

In a light emitting device 20 according to the embodiment of the present invention, a light emitting element 23, which is an excitation light source, is mounted at a center of the surface of the disk-shaped circuit substrate 22. Further, a dome-shaped luminescent body 25 is formed on the circuit substrate 22 so as to surround the light emitting element 23.

The light emitting element 23, which emits excitation light for exciting the luminescent body 25, is formed by a light emitting diode or the like. The light emitting element 23 is electrically connected to the circuit substrate 22 through a bonding wire 24.

In the embodiment of the present invention, the luminescent body 25 is a molded body, in which ground particles of a polycrystal sintered body (one of Examples 1 through 4) of Tb:YAG having the concentration of Tb provided in the present invention are dispersed in a light transmissive resin binder, such as a (meth) acrylic-based resin binder. The polycrystal sintered body of Tb:YAG that has the concentration of Tb provided in the present invention has an excellent transparency characteristic, and the Tb concentration C(Tb/A) is within the range of more than 10 mol % to 55.0 mol % inclusive. Optionally, the Tb concentration C(Tb/A) is within the range of 20.0 to 40.0 mol %.

The luminescent body 25 can be produced in the following manner. A polycrystal sintered body of Tb:YAG of the present invention is ground in a mortar to obtain ground particles. Then, the ground particles and a light transmissive resin, such as (meth)acrylic-based resin, are mixed and kneaded in a resin melt state to obtain a mixture (for example, Tb:YAG/PMMA resin=¾ (mass ratio)). Then, the circuit substrate 22 mounted with the light emitting element 23 is placed in a mold, and injection molding is performed to form the luminescent body 25.

Tb:YAG emits light within visible light wavelength region (400 to 700 nm) by being excited by light having a wavelength within the range of 220 nm to 500 nm. Therefore, the excitation light source should be selected based on the desirable wavelength of light to be emitted (please refer to FIG. 12A in Example 1). For example, when the excitation wavelength is within the range of ultraviolet light to visible light wavelength region, intense green fluorescence having a wavelength of 542 nm is emitted. Further, when the excitation wavelength is 377 nm, light is emitted in a most efficient manner (please refer to FIG. 12B in Example 1).

As the light emitting element 23, which is an excitation light source, a GaN-based light emitting diode (oscillation peak wavelength: 360 to 500 nm) including an active layer containing at least one of nitrogen-containing semiconductor compound, such as GaN, AlGaN, InGaN, InAlGaN, InGaNAs and GaNAs, a ZnSSe-based semiconductor light emitting diode (oscillation peak wavelength: 450 to 520 nm), a ZnO-based light emitting diode (oscillation peak wavelength: 360 to 450 nm) or the like is appropriate.

As described above, in the light emitting device 20 according to the embodiment of the present invention, the luminescent body 25 containing the compound of the present invention is used. Therefore, the light emitting device 20 has an excellent luminescence characteristic. Further, the light emitting device 20 can output highly bright visible light.

As described above in the section of “Background Technique”, in a white light LED, a method for obtaining white color by additive color mixture of blue, green and red, which are three primary colors of light, has been considered. Since the luminescent body 25 can act as a highly efficient green phosphor, as described above, the luminescent body 25 is appropriate as a green phosphor for a white LED, or the like, in which white light is obtained by additive color mixture of blue, green and red.

Therefore, in the light emitting device 20 according to the embodiment of the present invention, if an ultraviolet light source is used as the light emitting element 23, and if a molded body, in which ground particles of a polycrystal sintered body of Tb:YAG of the present invention, ground particles of a red fluorescent compound and ground particles of a blue fluorescent compound are dispersed in a light-transmissive resin binder such as (meth)acrylic-based resin, is used as the luminescent body 25, the light emitting device 20 according to the embodiment of the present invention can be used as a highly efficient white LED.

Further, when the light emitting element 23 is, for example, a blue visible light source, if the luminescent body 25 is produced using ground particles of the polycrystal sintered body of Tb:YAG of the present invention and ground particles of a red fluorescent compound, the light emitting device can be used as a white LED in a similar manner.

The compound, the composition and the luminescent body of the present invention may be utilized not only as the solid-state laser device or the light emitting device but also for various other purposes.

### EXAMPLES

Examples of the present invention will be described.

### Example 1

As described above, a polycrystal sintered body of Tb:YAG was prepared by using YAG(Y₃Al₅O₁₂) as a parent compound and by doping the parent compound with Tb. The following samples, 11 samples in total, were prepared by changing the concentration of Tb (“%” represents the Tb concentration C(Tb/A) mol %):

Sample 1: 0.0% Tb:YAG,

Sample 2: 1.0% Tb:YAG,

Sample 3: 5.0% Tb:YAG,

Sample 4: 10.0% Tb:YAG,

Sample 5: 15.0% Tb:YAG,

Sample 6: 30.0% Tb:YAG,

Sample 7: 40.0% Tb:YAG,

Sample 8: 50.0% Tb:YAG,

Sample 9: 60.0% Tb:YAG,

Sample 10: 80.0% Tb:YAG, and

Sample 11: 100.0% Tb:YAG.

First, each of Y₂O₃ powder (purity: 99.9%), α-Al₂O₃ powder (purity: 99.99%) and Tb₄O₇ powder (purity: 99.99%) was weighed so as to obtain desirable composition.

For example, in 1.0% Tb:YAG (sample 2, Y/Tb mole ratio=2.97/0.03), the composition of the raw material powder was set to 33.533 g of Y₂O₃ powder, 25.490 g of α-Al₂O₃ powder, and 0.561 g of Tb₄O₇ powder.

Then, the raw material powder, 100 mL of ethyl alcohol, and 150 pieces of 10 mm-diameter alumina balls were put into a pot mill and wet mixing processing was performed for 12 hours.

Then, the alumina balls were removed, and ethyl alcohol was removed from the obtained mixed powder slurry using a rotary evaporator. Further, the remaining mixture was dried at a temperature of 100° C. for 12 hours, and the obtained dry powder was slightly loosened in a mortar. Then, uniaxial compression molding processing was performed on the obtained dry powder at a molding pressure of 100 MPa to produce pellets (cylindrical shape) with a diameter of 10 mm and a height of 5 mm.

Further, preliminary firing process was performed on the obtained compression molded body. In the preliminary firing process, the obtained compression molded body was placed in an electric furnace under an air atmosphere. The temperature of the compression molded body was raised to 1450° C. at a rate of 500° C./hr and kept at 1450° C. for two hours. Then, the compression molded body was cooled down to a temperature of 1000° C. at a rate of 500° C./hr and naturally cooled in the furnace.

After the preliminarily sintered body was cooled down to a normal temperature, the preliminarily sintered body was ground in a mortar. As described above, the dry powder for sintering containing the composition elements of Tb:YAG was obtained by using the ordinary solid phase reaction ceramics method. The particle sizes and shapes of the dry powder for sintering are not uniform (they are random).

Then, uniaxial compression molding processing was performed on the obtained dry powder for sintering at a molding pressure of 100 MPa, and the dry powder for sintering was molded into a pellet (cylindrical shape) having a diameter of 10 mm and a height of 5 mm.

Then, main firing process was performed on the obtained compression molded body (powder-molded body). In the main firing process, the obtained compression molded body was placed in an electric furnace under an air atmosphere. The temperature of the compression molded body was raised to 1700° C. at a rate of 500° C./hr and kept at 1700° C. for two hours. Then, the compression molded body was cooled down to a temperature of 1000° C. at a rate of 500° C./hr and naturally cooled in the furnace. Accordingly, a polycrystal sintered body of Tb:YAG that has a desirable Tb concentration was obtained.

### <Powder X-Ray Diffraction (XRD) Measurement>

Each of samples 1 to 11 was ground in a mortar, and powder X-ray diffraction (XRD) measurement was performed on each of samples 1 to 11 using an X-ray diffraction apparatus produced by Rigaku Corporation. The measurement conditions were as follows: CuKα, 40 kV, 40 mA, scanning speed: 0.5 deg/min, and light receiving slit: 0.15 mm. FIGS. 9A and 9B are diagrams illustrating the XRD measurement results of major samples. In FIG. 9A, the XRD measurement results of samples 1 and 2 are illustrated. In FIG. 9B, the XRD measurement results of samples 4, 8 and 11 are illustrated. In each of the results, the diffraction peak was completely the same as that of JCPDS#33-0040 (YAG cubic crystal), and it was confirmed that these samples have single phase structure. This result shows that, in each of the cases of samples 2 through 11, in which the compounds were doped with Tb, all of the input Tb entered YAG, which is a parent compound, and Y at the 8-coordination site in the garnet structure was efficiently substituted by Tb through solid solution formation.

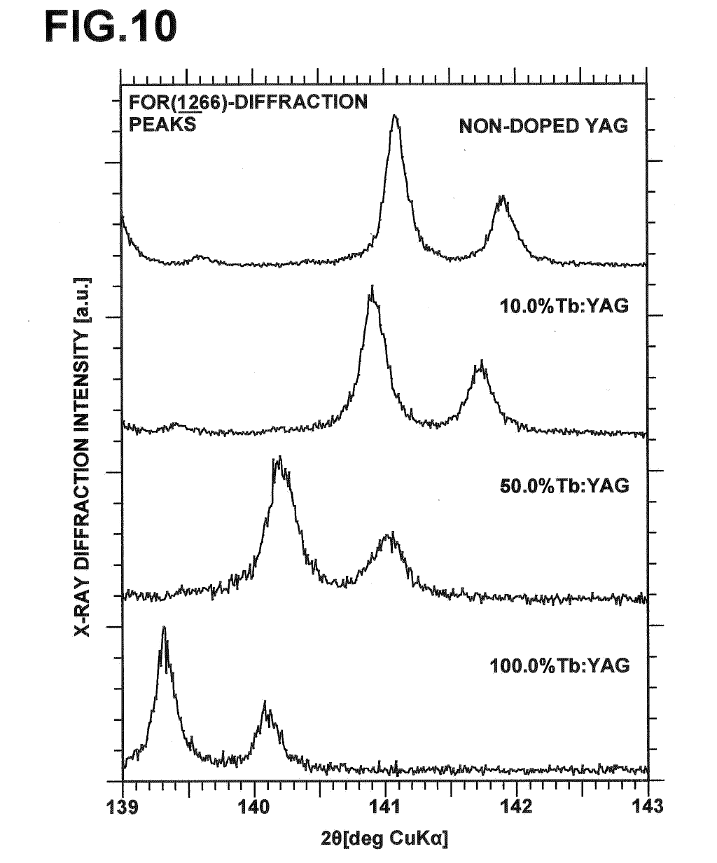

FIG. 10 is an enlarged graph showing the XRD behavior of each of the major samples in a high angle region. FIG. 10 illustrates the state in which as the concentration of Tb increases, the diffraction peak shifts to the low angle side, and the lattice expands.

### <Lattice Constant>

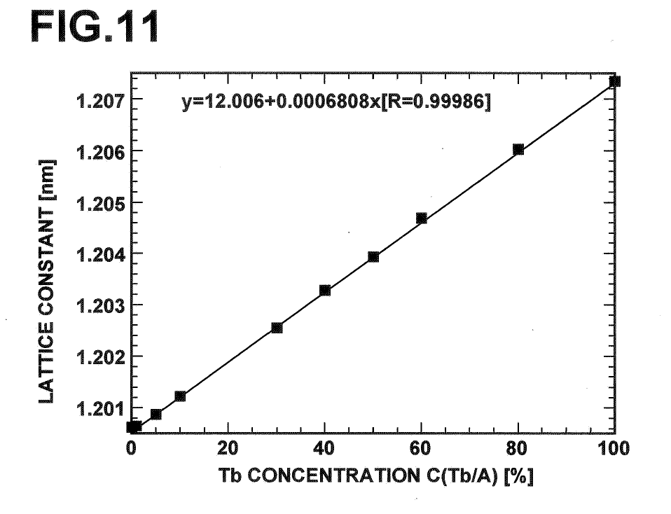

The inventors of the present invention obtained lattice constants based on the results of the XRD measurement. Specifically, a diffraction peak value of the YAG cubic crystal at 2θ=100° to 150° was obtained by using a tangential method, and an accurate lattice constant was calculated using Nelson-Riley function. FIG. 11 illustrates the calculated lattice constants.

The Nelson-Riley function is given by the formula:

½(cosθ)² (1/sinθ+1/θ)

The obtained values are plotted on the x axis, and lattice constants a obtained from the Bragg diffraction conditions are plotted on the y axis. The value of the y-intercept of the straight line of the least square method is obtained as a true lattice constant.

FIG. 11 shows that, in the entire range of the Tb concentration of 0 to 100 mol %, the lattice constants linearly increase as the concentration of Tb increases. This indicates that in the entire range of the Tb concentration of 0 to 100 mol %, substitution through solid solution formation was performed based on the Vegard's law, that all of input Tb entered YAG, which is the parent compound, and that Y at the 8-coordination site was efficiently substituted by Tb through solid solution formation.

In FIG. 11, a lattice constant when the concentration of Tb is 100 mol % (Y is completely substituted by Tb) is very close to the lattice constant (=1.2074 nm) of Tb₃Al₅O₁₂ of JCPDS#17-0735. Therefore, it can be judged that the evaluation in FIG. 11 is appropriate.

### <Luminescence Characteristics of 1.0% Tb:YAG>

As a typical example of a relatively low concentration, 1.0% Tb:YAG (sample 2) was selected, and luminescence spectrum (fluorescence spectrum) measurement was performed using Hitachi Fluorescence Spectrophotometer F-4500.

The wavelength λₑₓ of the excitation light was set to 377 nm, at which the intensity of luminescence was the highest when an excitation spectrum was obtained. The luminescence spectrum is illustrated in FIG. 12A. A multiplicity of luminescence peaks were observed in the wavelength region of 400 to 700 nm, which is a visible light wavelength region, and the highest luminescence peak was observed at 542 nm.

Next, excitation spectrum measurement was performed on the same sample. An excitation spectrum represents the intensity of luminescence (intensity of fluorescence) at the highest luminescence peak wavelength (542 nm) within the visible light wavelength region with respect to the excitation wavelength. The excitation spectrum is illustrated in FIG. 12B (in FIG. 12B, mark “x” represents leakage of higher order light of excitation light.)

In the excitation spectrum illustrated in FIG. 12B, a multiplicity of excitation peaks are observed in a wavelength region shorter than or equal to 500 nm. Of the plurality of the excitation peak wavelengths in the wavelength region shorter than 500 nm, the excitation peak wavelength, at which absorption is the highest and the intensity of fluorescence is the highest, is 377 nm. Further, absorption is high and the intensity of fluorescence is high at 370 nm, 360 nm and 230 nm, which is in a deep ultraviolet wavelength region. This indicates that luminescence at 542 nm can be obtained by being excited by light of 377 nm, 370 nm, 360 nm, 230 nm or the like.

The wavelength of 377 nm is within the oscillation wavelength range of a laser diode, such as a GaN-based laser diode and a ZnO-based laser diode. Therefore, it was confirmed that an existing light source can be used as the excitation light source of Tb:YAG.

Next, the fluorescence lifetime of 1.0% Tb:YAG (sample 2) was measured using Picosecond Fluorescence Lifetime Measurement Apparatus C4780, produced by Hamamatsu Photonics K.K. As an excitation light source, a nitrogen laser excitation pigment laser (10 Hz) was used, and a wavelength of 377 nm was selected and excited.

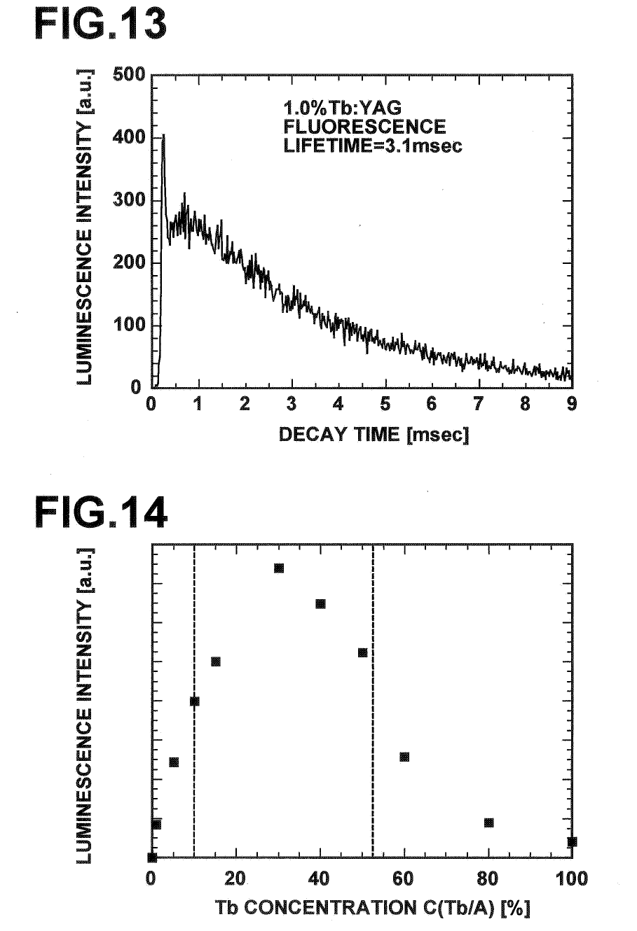

The measurement result is illustrated in FIG. 13. If an inverted distribution necessary for laser oscillation is taken into consideration, it is considered that a sufficiently long lifetime is necessary to use sample 2 as a solid-state laser medium. As illustrated in FIG. 13, the fluorescence lifetime of 1.0% Tb:YAG was 3.1 milliseconds. It was confirmed that 1.0% Tb:YAG has a sufficiently long fluorescence lifetime as the solid-state laser medium.

### <Relationship between Concentration and Luminescence Characteristic>

The luminescence spectrum measurement was performed on the other samples in the same manner as the measurement performed on sample 2. The relationship between the concentration of Tb and the intensity of luminescence at the wavelength of 542 nm when the excitation wavelength is 377 nm is illustrated in FIG. 14.

The inventors of the present invention have found that Tb:YAG exhibits a luminescence characteristic in the entire range of the Tb concentration C(Tb/A) of more than 0 mol % to 100 mol % inclusive. Particularly, high luminescence intensity is obtained in the range of the Tb concentration (Tb/A) of more than 10.0 mol % to 55.0 mol % inclusive (corresponding to a Tb concentration C(Tb/all) within the range of more than 3.75 mol % to 20.625 mol % inclusive). Since it used to be considered that an appropriate Tb concentration C(Tb/A) in Tb:YAG is 10 mol % or less, there was no report on the evaluation result of the intensity of luminescence for the case in which C(Tb/A) is more than 10 mol %.

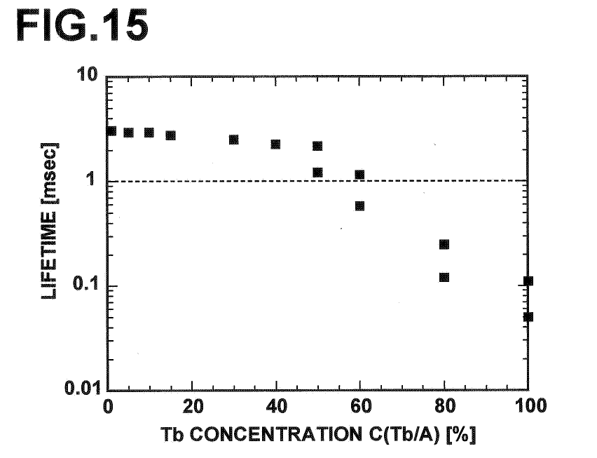

Further, the fluorescence lifetime of each of the other samples was measured in a manner similar to the measurement performed on sample 2. FIG. 15 illustrates the relationship between the concentration of Tb and the fluorescence lifetime when the excitation wavelength is 377 nm.

In FIG. 15, when the Tb concentration C(Tb/A) is more than or equal to 50.0 mol %, two relaxation composition elements are observed. When Tb:YAG has a Tb concentration C(Tb/A) of 50.0 mol %, the two composition elements have long fluorescence lifetimes of the order of milliseconds. Therefore, the inventors of the present invention have found that Tb:YAG has a long fluorescence lifetime of the order of milliseconds in a wide range of Tb concentration C(Tb/A) of more than 0.0 mol % to 50.0 mol % inclusive (corresponding to C(Tb/all)=more than 0.0 mol % to 18.50 mol % inclusive).

In most of the luminescent rare earth elements, attenuation of luminescence (referred to as concentration quenching) due to high concentration doping occurs on the low doping concentration side. However, in the case of Tb:YAG, such concentration quenching does not occur even at a high concentration. Even if a compound is doped with Tb at a high concentration, concentration quenching tends not to occur. Further, Tb:YAG is useful because Tb:YAG has a long fluorescence lifetime. Tb:YAG is useful as a material for a solid-state laser medium, because it is possible to increase the absorption amount of excitation light or the like.

In this example, polycrystal Tb:YAG was used and the luminescence characteristic or the like of the polycrystal Tb:YAG was evaluated. However, it can be considered that single crystal Tb:YAG has a similar characteristic.

### <Observation Using Scanning-Type Electron Microscope (SEM)>

A cross-section of each of the polycrystal sintered bodies of samples 1 to 11 was observed using a scanning-type electron microscope (SEM). According to the observation, the sizes and shapes of the crystal grains were not uniform (the sizes and shapes were random) (please refer to FIG. 1A).

### Example 2

A 30.0% Tb:YAG polycrystal sintered body (transparent ceramics, Y/Tb mole ratio=2.10/0.90) was prepared in the following manner. In this example, SiO₂, which acts as a sintering aid, was added. The raw material powder was prepared so that 1.0 mol % of the Al site is substituted by Si.

First, each of Y₂O₃ powder (purity: 99.9%), α-Al₂O₃ powder (purity: 99.99%), Tb₄O₇ powder (purity: 99.99%), and SiO₂ powder (purity: 99.99%) was weighed so that desirable composition is obtained.

Wet mixing of the raw material powder, drying of the mixed powder slurry, compression molding of the dry powder, and preliminary firing process at 1450° C. were performed in the same manner as the processing in Example 1. Then, the preliminary sintered body was ground in a mortar.

Next, the obtained ground particles and ethanol were mixed together so as to form slurry having a high viscosity. Then, ball-mill grinding was performed on the slurry for 24 hours, and the slurry was dried. As described above, dry powder for sintering containing the composition elements of Tb:YAG was obtained by using an ordinary solid phase reaction ceramics method. In the dry powder for sintering, the sizes and the shapes of particles are not uniform (the sizes and the shapes are random). Then, uniaxial compression molding processing was performed on the obtained dry powder for sintering at a molding pressure of 100 MPa to form a pellet (cylindrical shape) having a diameter of 10 mm and a height of 5 mm.

Then, preliminary firing process was performed on the obtained compression molded body (powder molded body). In the preliminary firing process, the compression molded body was placed in an electric furnace under an air atmosphere. Then, the temperature of the compression molded body was raised to 1450° C. at a rate of 500° C./hr and kept at 1450° C. for two hours. Then, the compression molded body was cooled down to a temperature of 1000° C. at a rate of 500° C./hr and naturally cooled in the furnace.

Next, main firing process was performed. In the main firing process, grinding was not performed, and the preliminary fired body was placed, under a vacuum atmosphere (1.0×10⁻³ Pa), in an electric furnace that can perform vacuum firing. Then, the temperature of the preliminary fired body was raised to 1750° C. at a rate of 500° C./hr and kept at 1750° C. for 15 hours. Then, the preliminary fired body was cooled down to a temperature of 1000° C. at a rate of 500° C./hr and naturally cooled in the furnace. Further, the two surfaces of the obtained body were polished, and a polycrystal sintered body of Tb:YAG (Si added) having a desirable appropriate Tb concentration was obtained.

The obtained polycrystal sintered body had an excellent transparency characteristic. It was confirmed that a transparent ceramic material that has an excellent transparency characteristic as a solid-state laser medium or the like can be obtained by performing the process in this example.

The obtained polycrystal sintered body was ground, and XRD measurement was performed in a manner similar to the processing in Example 1. Then, it was confirmed that all of diffraction peaks coincided with those of JCPDS#33-0040 (YAG cubic crystal), and that the ground particles had single phase structure.

### Example 3

A 30% Tb:YAG polycrystal sintered body (transparent ceramics) was prepared in the following manner.

First, powder for sintering was prepared by using an alkoxide emulsion method. As raw-material metal alkoxides, each of 2.80 g of Y(iso-OPr)₃ powder (purity: 99.9%), 6.16 g of an Al(sec-OBu)₃ gel-like material (purity: 99.99%), and 1.5 g of Tb(iso-OPr)₃ powder (purity: 99.9%) was weighed. These metal alkoxides were put in 52.9 mL of 1-octanol and stirred at 120° C. for 12 hours under an N₂ gas flow in a flask made of Pyrex (trademark) so as to be dissolved.

After the solution was cooled down to the room temperature, 36.36 mL of acetonitrile and 0.02 g of hydroxypropyl cellulose (as a dispersion agent) were added to the solution, and stirred for five minutes. Accordingly, an alkoxide emulsion was obtained. After the temperature of the alkoxide emulsion was raised to 40° C., a 1-octanol/acetonitrile/water mixed liquid (composition ratio: 2.46 mL/1.64 mL/0.90 mL) was added to the obtained alkoxide emulsion. The mixture was stirred at 40° C. for one hour, and hydrolysis of alkoxide was performed. Accordingly, a multiplicity of particles were obtained.

Next, centrifugal separation processing was performed using a centrifugal separator under conditions of 500 rpm for 10 minutes, and the powder was separated and collected. Further, the collected powder was dispersed in ethanol, and centrifugal separation processing under conditions of 5000 rpm for 10 minutes was performed twice. Then, the powder was washed, and dried at 80° C. for 24 hours using a drier. Accordingly, powder for sintering was obtained.

The powder for sintering was observed using the scanning-type electron microscope (SEM). According to the observation, the obtained powder for sintering was formed by substantially spherical fine particles, and the sizes and the shapes of the particles were uniform.

Uniaxial compression molding (preliminary molding) was performed on the obtained powder for sintering at a molding pressure of 10 MPa. Further, CIP processing was performed at 140 MPa. Accordingly, a compression molded body (powder molded body) in a pellet form (a cylindrical shape) that has a diameter of 10 mm and a height of 5 mm was obtained.

Then, preliminary firing process was performed on the obtained compression molded body (powder molded body). In the preliminary firing process, the compression molded body was placed in an electric furnace under an air atmosphere. Then, the temperature of the compression molded body was raised to 1400° C. at a rate of 500° C./hr and kept at 1400° C. for two hours. Then, the compression molded body was cooled down to a temperature of 1000° C. at a rate of 500° C./hr and naturally cooled in the furnace.

Next, main firing process was performed. In the main firing process, grinding processing was not performed, and the preliminary fired body was placed, under a vacuum atmosphere (1.0×10⁻³ Pa), in an electric furnace that can perform vacuum firing. Then, the temperature of the preliminary fired body was raised to 1750° C. at a rate of 500° C./hr and kept at 1750° C. for 10 hours. Then, the preliminary fired body was cooled down to a temperature of 1000° C. at a rate of 500° C./hr and naturally cooled in the furnace. Further, the two surfaces of the obtained body were polished, and a polycrystal sintered body of Tb:YAG having a desirable Tb concentration was obtained.

The obtained polycrystal sintered body had an excellent transparency characteristic. It was confirmed that a transparent ceramic material that has an excellent transparency characteristic as a solid-state laser medium or the like can be obtained by performing the process in this example.

The obtained polycrystal sintered body was ground, and XRD measurement was performed in a manner similar to the processing in Example 1. Then, it was confirmed that all of diffraction peaks coincide with those of JCPDS#33-0040 (YAG cubic crystal), and that the ground particles had single phase structure.

### Modification to Example 3

The powder obtained by using the alkoxide emulsion method, and which was used for sintering, may be decarbonized by thermally processing the powder at 600° C. for 12 hours or the like to obtain amorphous powder substantially containing only Y, Al, Tb, and O. Then, the obtained amorphous powder may be used as powder for sintering. The amorphous powder may be further polycrystallized by thermally processing the amorphous powder at 1200° C. for two hours or the like. Accordingly, polycrystal powder substantially containing only Y, Al, Tb and O is obtained, and this polycrystal powder may be used as powder for sintering. The inventors of the present invention have confirmed that a polycrystal sintered body of Tb:YAG having an excellent transparency characteristic can be obtained using such powder for sintering in a manner similar to Example 3.

### Example 4

A 30% Tb:YAG polycrystal sintered body (transparent ceramics) was prepared in the following manner.

First, powder for sintering was prepared by using the hydrothermal synthesis method.

4.742 g of yttrium oxide (Y₂O₃) powder (purity: 99.99%) was accurately weighed and put in a beaker. Then, an excess aqueous concentrated nitric acid solution was slowly poured into the beaker. The mixture was stirred while heated so as to completely dissolve the yttrium oxide in the aqueous concentrated nitric acid solution. Then, the solution was solidified by being dried by evaporation. After cooling down to a normal temperature, a small quantity of an aqueous nitric acid solution (for example, two or three droplets of 35% concentrated nitric acid) and 8.155 g of terbium nitrate hexahydrate (Tb(NO₃)₃·6H₂O) were added and stirred. Accordingly, 30 to 50 mL of an aqueous solution (an aqueous Y+Tb solution) containing Y ions and Tb ions was prepared.

Separately, 13.334 g of anhydrous aluminum chloride (AlCl₃) powder (purity: 99.99%) was accurately weighed and slowly added to a different beaker containing water. Then, the mixture was stirred so as to completely dissolve the anhydrous aluminum chloride in the water. Accordingly, 30 to 50 mL of aqueous solution (an aqueous Al solution) containing Al ions was prepared.

Further, an aqueous high-concentration solution (99.99%) of potassium hydroxide (KOH) was prepared in a different beaker.

After the three beakers were prepared, the aqueous Y+Tb solution and the aqueous Al solution were mixed together. Then, an aqueous high-concentration KOH solution was gradually added to the mixed solution while stirring. The aqueous high-concentration KOH solution was added while a pH meter was being monitored. The mixed solution gelled as the pH value of the solution changed, but stirring was continued. When the pH value reached 12.0, addition of the aqueous high-concentration KOH solution was stopped. Accordingly, a raw material liquid (pH=12.0, 200 mL) for hydrothermal synthesis reaction was prepared.

The raw material liquid was loaded into an autoclave made of HASTELLOY (trademark). Then, the raw material liquid was caused to hydrothermally react at 360° C. for two hours in a reaction vessel having an inner surface on which platinum lining processing had been performed while the raw material liquid was being stirred.

After the reaction ends, the liquid in the reaction vessel was transferred to a beaker, and a decantation process, in which hot water is added and only supernatant is discarded, was repeated at least ten times. Finally, a reaction precipitate was collected by filtration, and powder for firing was obtained. The powder for firing contained moisture. However, the powder was provided for the next step without drying.

A part of the reaction precipitate obtained after the hydrothermal synthesis reaction was not provided for production of a polycrystal sintered body. The part of the reaction precipitate was dried and provided for evaluation. Then, XRD measurement was performed on the powder obtained by drying the reaction precipitate. Then, it was confirmed that all of diffraction peaks coincided with those of JCPDS#33-0040 (YAG cubic crystal), and that the powder had single phase structure. Further, SEM observation was performed, and the inventors of the present invention found that the powder was formed by a multiplicity of fine particles having rhombic dodecahedral-shapes, of which the sizes were substantially the same. The powder contained particles that had uniform sizes and shapes.

As a dispersion medium, 10 mL of ethanol was added to approximately 5 g of the powder for firing that had not been dried, and mixed with each other. The mixture was poured into a vessel having a very smooth bottom surface, and fine particles were slowly sedimented. As the dispersion medium, polyvinyl butyral or the like may be used.

Then, the supernatant was gently removed, and the powder was naturally dried. Accordingly, a pancake-shaped powder molded body was obtained. In this process, after the supernatant was gently removed, the vessel may be mounted on an antivibration table and the powder may be dried under reduced pressure to obtain a pancake-shaped powder molded body.

Next, firing process was performed on the powder molded body. In the firing process, the powder molded body was placed in an electric furnace that can perform vacuum firing. Then, the temperature of the powder molded body was raised to 1750° C. at a rate of 500° C./hr under a vacuum atmosphere (1.0×10⁻³ Pa), and kept at 1750° C. for five hours. Then, the powder molded body was cooled down to a temperature of 1000° C. at a rate of 500° C./hr, and naturally cooled in the furnace. Further, the two surfaces of the fired body were polished. Accordingly, a polycrystal sintered body of Tb:YAG having a desirable Tb concentration was obtained.

The obtained polycrystal sintered body had an excellent transparency characteristic. It has been confirmed that, by performing the process of this example, a transparent ceramic material that has an excellent transparency characteristic as a solid-state laser medium or the like can be obtained.

SEM Observation was performed on the obtained polycrystal sintered body. The polycrystal sintered body was formed by an aggregate of a multiplicity of rhombic dodecahedral crystal grains that have substantially the same sizes (crystal grain diameter: approximately 8.5 μm). Further, the polycrystal sintered body was formed by particles that have uniform sizes and shapes, and the space filling rate of the polycrystal sintered body was high.

In this example, the powder for sintering formed by rhombic dodecahedral fine particles was prepared. However, if the reaction condition (temperature, time or the like) in the hydrothermal reaction is changed, it is possible to prepare powder for sintering formed by truncated octahedral fine particles (please refer to FIG. 4).

The Tb-doped luminescent compound of the present invention is appropriate as a solid-state laser medium, a phosphor for a white-light emitting diode, or the like.

What is claimed is:

1. A Tb-doped luminescent compound containing Tb and at least two kinds of metal elements other than Tb, and emitting light by irradiation with excitation light, wherein the concentration of Tb with respect to the total number of moles of all of the metal elements including Tb is within the range of more than 3.75 mol % to 20.625 mol % inclusive.

2. A Tb-doped luminescent compound, as defined in claim 1, wherein the Tb-doped luminescent compound has garnet-type crystal structure.

3. A Tb-doped luminescent compound, as defined in claim 2, wherein the Tb-doped luminescent compound is represented by the following general formula:
(A(III)₁₋ₓTbₓ)₃B(III)₂C(III)₃O₁₂, where each of the Roman numerals in the parentheses represents the valence of an ion, A is at least one kind of element selected from the group consisting of Sc, Y, In, La, Ce, Pr, Nd, Sm, Gd, Dy, Ho, Er, Tm, Yb and Lu, B is at least one kind of element selected from the group consisting of Al, Sc, Cr, Ga, In, Sm, Eu, Gd, Dy, Ho, Er, Tm, Yb and Lu, C is at least one kind of element selected from the group consisting of Al and Ga, O is an oxygen atom, and 0.1<x≦0.55.

4. A Tb-doped luminescent compound, as defined in claim 3, wherein the value of x satisfies 0.2≦x≦0.4.

5. A Tb-doped luminescent compound, as defined in claim 3, wherein A(III) is Y, B(III) is Al, and C(III) is Al.

6. A luminescent composition containing the Tb-doped luminescent compound defined in claim 1.

7. A luminescent body having a luminescence characteristic, the luminescent body emitting light by irradiation with excitation light, the luminescent body further having a predetermined shape, wherein the luminescent body contains the Tb-doped luminescent compound defined in claim 1.

8. A luminescent body, as defined in claim 7, wherein the luminescent body is a polycrystal sintered body obtained by sintering a powder-molded body, and wherein the powder-molded body is obtained by forming at least one kind of raw material powder containing the composition elements of the Tb-doped luminescent compound into a predetermined shape.

9. A luminescent body, as defined in claim 8, wherein the polycrystal sintered body is formed by an aggregate of a multiplicity of crystal grains having substantially the same sizes and shapes, and wherein the shape of each of the crystal grains is a polyhedral shape that enables the crystal grains to solely fill the entire space of the polycrystal sintered body substantially without any empty space therebetween.

10. A luminescent body, as defined in claim 9, wherein the shape of each of the crystal grains is one of a cubic shape, a truncated octahedral shape and a rhombic dodecahedral shape.

11. A luminescent body, as defined in claim 8, wherein the raw material powder is synthesized by using one of a hydrothermal synthesis method and an alkoxide emulsion method.

12. A luminescent body, as defined in claim 7, wherein the luminescent body is a molded body formed by binding Tb-doped luminescent compound in a powder state together using a resin binder.

13. A luminescent body, as defined in claim 7, wherein the Tb-doped luminescent compound is a laser material that emits laser light by being excited by excitation light.

14. A light emitting device comprising:
the luminescent body defined in claim 7; and
an excitation light source for irradiating the luminescent body with excitation light.

15. A light emitting device, as defined in claim 14, wherein the excitation light source emits light having a wavelength within the range of 350 to 470 nm.

16. A light emitting device, as defined in claim 15, wherein the excitation light source is one of a GaN-based light emitting diode and a ZnO-based light emitting diode.

17. A solid-state laser device comprising:
a solid-state laser medium; and
an excitation light source for irradiating the solid-state laser medium with excitation light, wherein the solid-state laser medium is the luminescent body defined in claim 13.

18. A solid-state laser device comprising:
a solid-state laser medium; and
an excitation light source for irradiating the solid-state laser medium with excitation light, wherein the solid-state laser medium contains a Tb-doped oxide.

19. A solid-state laser device, as defined in claim 18, wherein the Tb-doped oxide is a garnet-type compound.

20. A solid-state laser device, as defined in claim 19, wherein the Tb-doped oxide is represented by the following general formula:
(A(III)₁₋ₓTbₓ)₃B(III)₂C(III)₃O₁₂, where each of the Roman numerals in the parentheses represents the valence of an ion, A is at least one kind of element selected from the group consisting of Sc, Y, In, La, Ce, Pr, Nd, Sm, Gd, Dy, Ho, Er, Tm, Yb and Lu, B is at least one kind of element selected from the group consisting of Al, Sc, Cr, Ga, In, Sm, Eu, Gd, Dy, Ho, Er, Tm, Yb and Lu, C is at least one kind of element selected from the group consisting of Al and Ga, O is an oxygen atom, and 0<x<1.

21. A solid-state laser device, as defined in claim 20, wherein A(III) is Y, B(III) is Al, and C(III) is Al.

22. A solid-state laser device, as defined in claim 17, wherein the excitation light source is a semiconductor laser that emits light having a wavelength within the range of 350 to 470 nm.

23. A solid-state laser device, as defined in claim 18, wherein the excitation light source is a semiconductor laser that emits light having a wavelength within the range of 350 to 470 nm.

24. A solid-state laser device, as defined in claim 22, wherein the semiconductor laser is one of a GaN-based semiconductor laser and a ZnO-based semiconductor laser.

25. A solid-state laser device, as defined in claim 23, wherein the semiconductor laser is one of a GaN-based semiconductor laser and a ZnO-based semiconductor laser.

26. A solid-state laser device, as defined in claim 17, wherein the solid-state laser device emits laser light having a wavelength within the range of 470 to 640 nm.

27. A solid-state laser device, as defined in claim 18, wherein the solid-state laser device emits laser light having a wavelength within the range of 470 to 640 nm.

28. A solid-state laser device, as defined in claim 17, the solid-state laser device further comprising:
a wavelength conversion device for converting the wavelength of the laser light emitted from the solid-state laser medium.

29. A solid-state laser device, as defined in claim 18, the solid-state laser device further comprising:
a wavelength conversion device for converting the wavelength of the laser light emitted from the solid-state laser medium.

30. A solid-state laser device, as defined in claim 28, wherein the wavelength of laser light emitted from the solid-state laser device is within the range of 235 to 320 nm.

31. A solid-state laser device, as defined in claim 29, wherein the wavelength of laser light emitted from the solid-state laser device is within the range of 235 to 320 nm.
